(19) United States
(12) Patent Application Publication
(10) Pub. No.: US 2026/0302747 A1
(43) Pub. Date: Oct. 1, 2026

(54) BUSBAR AND ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Kazuhiko Tsuchiya, Kakegawa-shi (JP)

(21) Appl. No.: 19/344,519

(22) Filed: Sep. 30, 2025

(30) Foreign Application Priority Data
Oct. 7, 2024 (JP) 2024-176060

(51) Int. Cl. H02G 3/16; H02B 1/20; H02G 3/08

(52) U.S. Cl. CPC H02G 3/16; H02B 1/20; H02G 3/081

(57) ABSTRACT

A bus bar includes a first connection portion and a first extending portion. The first connection portion is connected to a first terminal of an electronic component directly or via a first connection component. The first extending portion extends from the first connection portion. In a case where a thickness direction of the first extending portion is a first direction, an extending direction of the first extending portion is a second direction, and a direction intersecting the first direction and the second direction is a third direction, a width of the first connection portion in the third direction is larger than a width of the first extending portion in the third direction.

### TECHNICAL FIELD

Embodiments of the present invention relate to a bus bar and an electrical connection unit.

Priority is claimed on Japanese Patent Application No. 2024-176060 filed in Japan on Oct. 7, 2024, the content of which is incorporated herein by reference.

### BACKGROUND ART

An electrical connection unit having an electronic component and a bus bar electrically connected to the electronic component is known.

### PRIOR ART DOCUMENTS

### Patent Documents

[Patent Document 1] Japanese Unexamined Patent Application, First Publication No. 2024-037492

### SUMMARY OF THE INVENTION

### Problems to be Solved by the Invention

Incidentally, it is expected to improve thermal characteristics of an electrical connection unit.

An embodiment provides a bus bar and an electrical connection unit that can improve thermal characteristics.

### Means for Solving the Problem

A bus bar according to an embodiment includes a first connection portion and a first extending portion. The first connection portion is connected to a first terminal of an electronic component directly or via a first connection component. The first extending portion extends from the first connection portion. In a case where a thickness direction of the first extending portion is a first direction, an extending direction of the first extending portion is a second direction, and a direction intersecting the first direction and the second direction is a third direction, a width of the first connection portion in the third direction is larger than a width of the first extending portion in the third direction.

An electrical connection unit of an embodiment includes an electronic component and a bus bar. The bus bar includes a first connection portion and a first extending portion. The first connection portion is connected to a first terminal of an electronic component directly or via a first connection component. The first extending portion extends from the first connection portion. In a case where a thickness direction of the first extending portion is a first direction, an extending direction of the first extending portion is a second direction, and a direction intersecting the first direction and the second direction is a third direction, a width of the first connection portion in the third direction is larger than a width of the first extending portion in the third direction.

### Effects of Invention

According to one embodiment, it is possible to improve thermal characteristics.

### BRIEF DESCRIPTION OF THE DRAWINGS

FIG. 1 A cross-sectional view illustrating an electrical connection unit of an embodiment.

FIG. 2 A perspective view for describing a main body of the embodiment.

FIG. 3 A perspective view for describing one subunit of the embodiment.

FIG. 4 A perspective view illustrating an electronic component and a connection component of the embodiment.

FIG. 5 A perspective view for describing a routing board of the embodiment.

FIG. 6 A partially exploded perspective view of the routing board of the embodiment.

FIG. 7 A plan view illustrating a subunit of the embodiment.

FIG. 8 A cross-sectional view taken along line F8-F8 of a structure illustrated in FIG. 7.

FIG. 9 A cross-sectional view taken along line F9-F9 of the structure illustrated in FIG. 7.

FIG. 10 A plan view for describing a first shape example of a bus bar of the embodiment.

FIG. 11 A plan view for describing a second shape example of the bus bar of the embodiment.

FIG. 12 A perspective view illustrating another subunit of the embodiment.

FIG. 13 A front view illustrating an electronic component of an embodiment.

FIG. 14 A perspective view illustrating a base member of the embodiment.

FIG. 15 A plan view illustrating a subunit of the embodiment.

FIG. 16 A cross-sectional view taken along line F16-F16 of a structure illustrated in FIG. 15.

FIG. 17 A cross-sectional view taken along line F17-F17 of the structure illustrated in FIG. 15.

FIG. 18 A cross-sectional view taken along line F18-F18 of the structure illustrated in FIG. 15.

FIG. 19 A cross-sectional view illustrating a subunit of a first modification example of the embodiment.

FIG. 20 A cross-sectional view illustrating a subunit of a second modification example of the embodiment.

FIG. 21 A cross-sectional view illustrating a subunit of a third modification example of the embodiment.

FIG. 22 A cross-sectional view illustrating a subunit of a fourth modification example of the embodiment.

FIG. 23 A perspective view illustrating a coupling structure between a plurality of subunits of the embodiment.

FIG. 24 A cross-sectional view taken along line F24-F24 of the structure illustrated in FIG. 15.

### EMBODIMENTS FOR CARRYING OUT THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

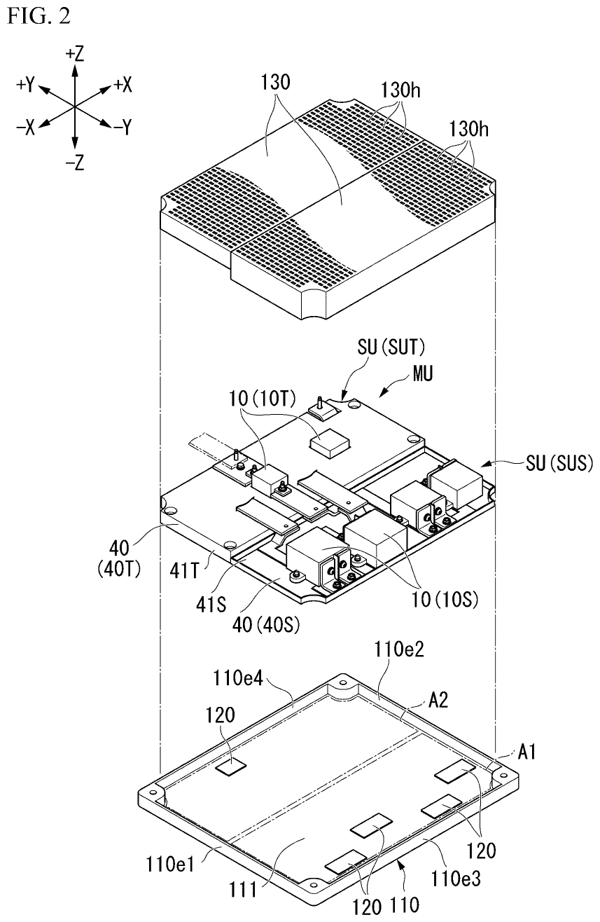

In the present disclosure, a +X direction, a −X direction, a +Y direction, a −Y direction, a +Z direction, and a −Z direction are defined as follows. The +X direction is a direction from a first end 110e1 to a second end 110e2 of a metal plate 110 that will be described later (see FIG. 2). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 110e3 to a fourth end 110e4 of the metal plate 110 that will be described later (see FIG. 2). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 110 that will be described later toward a main body MU (see FIG. 2). The −Z direction is a direction opposite to the +Z direction. Hereinafter, in a case where the +Z direction and the −Z direction are not distinguished, the directions will be simply referred to as “Z direction”. The Z direction is an example of a “first direction”. The Y direction is an example of “second direction”. The X direction is an example of a “third direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### Embodiment

### <1. Constitution of Electrical Connection Unit>

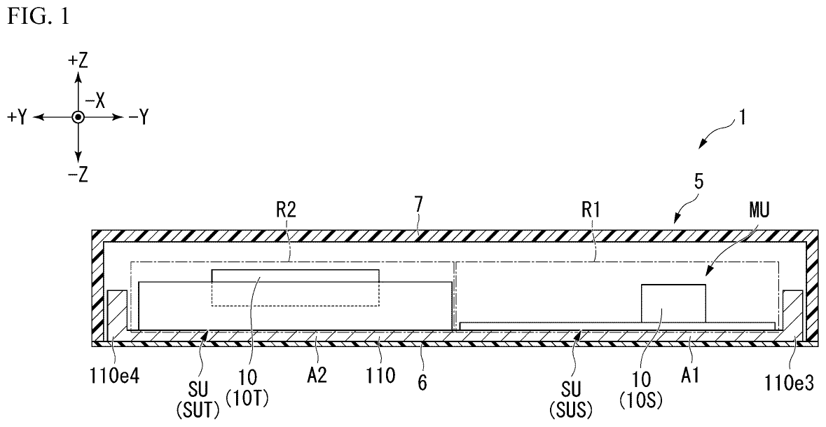

FIG. 1 is a cross-sectional view illustrating an electrical connection unit 1 of an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a casing 5, a main body MU, a metal plate 110, a plurality of heat transfer members 120 (see FIG. 2), and a plurality of insulating covers 130 (see FIG. 2).

### <2. Casing>

First, the casing 5 will be described. The casing 5 forms an outline of the electrical connection unit 1. The casing 5 includes, for example, a base 6 (first member) and a cover 7 (second member). The base 6 is a member that covers the main body MU and the metal plate 110 from below. The base 6 has, for example, a plate shape formed in the horizontal direction or a bowl shape open in the +Z direction. The base 6 is made of, for example, a synthetic resin. The cover 7 is a member that covers the main body MU and the metal plate 110 from above. The base 6 has, for example, a bowl shape open in the −Z direction. The cover 7 is made of, for example, a synthetic resin. In the present embodiment, the box-shaped casing 5 is formed by combining the base 6 and the cover 7. The shape of the casing 5 is not limited to the above example. For example, the metal plate 110 that will be described later may function as a part or the whole of the base 6. The casing 5 may be omitted.

In the present embodiment, the electrical connection unit 1 includes a first region (first space) R1 and a second region (second space) R2. The first region R1 is a region in which a heat dissipation property is emphasized. In the first region R1, for example, an electronic component 10S having a great amount of heat generation is disposed. On the other hand, the second region R2 is a region in which a mountability is emphasized. In the second region R2, for example, an electronic component 10T that has a smaller amount of heat generation than the electronic component 10S and/or requires a more complicated mounting structure than the electronic component 10S is disposed. However, these contents do not limit the contents of the electrical connection unit 1 of the present disclosure. For example, the amount of heat generation of the electronic component 10T may be greater than the amount of heat generation of the electronic component 10S.

### <3. Main Body>

Next, the main body MU will be described.

FIG. 2 is a perspective view for describing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting the plurality of subunits SU, for example. In the present embodiment, the main body MU includes two subunits SU (subunits SUS and SUT). Each subunit SU may be referred to as a “circuit constitution body”.

The subunit SUS has an electrical first function. The subunit SUS includes, for example, a plurality of electronic components 10S and a routing board 40S. The plurality of electronic components 10S are electrically connected to the routing board 40S. The base plate 41S (that will be described later) included in the subunit SUS is an example of a “first base member”.

The subunit SUT has an electrical second function. The second function is, for example, a function different from the first function. The subunit SUT includes, for example, a plurality of electronic components 10T and a routing structure 40T. The plurality of electronic components 10T are electrically connected to the routing structure 40T. The base member 41T (that will be described later) included in the subunit SUT is an example of a “second base member”.

In the present embodiment, the subunit SUS is a subunit SU in which a heat dissipation property is emphasized. The subunit SUS is disposed in the above first region R1 of the electrical connection unit 1. The subunit SUS faces a first region A1 of the metal plate 110 that will be described later in the Z direction.

On the other hand, the subunit SUT is a subunit SU in which the mountability is emphasized. The subunit SUT is disposed, for example, on the +Y direction side with respect to the subunit SUS. The subunit SUT is disposed in the above second region R2 of the electrical connection unit 1. The subunit SUT faces a second region A2 of the metal plate 110 that will be described later in the Z direction. Hereinafter, in a case where the electronic component 10S and the electronic component 10T are not distinguished, the electronic components are simply referred to as “electronic component 10”.

Note that the main body MU need not be divided into a plurality of subunits SU instead of the example described above. For example, the plurality of subunits SU may be integrally formed. For example, a base plate 41S of the routing board 40S and a base member 41T of the routing structure 40T, which will be described later, may be integrally formed by one piece member.

### <4. Constitution of Subunit SUS>

Next, a constitution of the subunit SUS will be described.

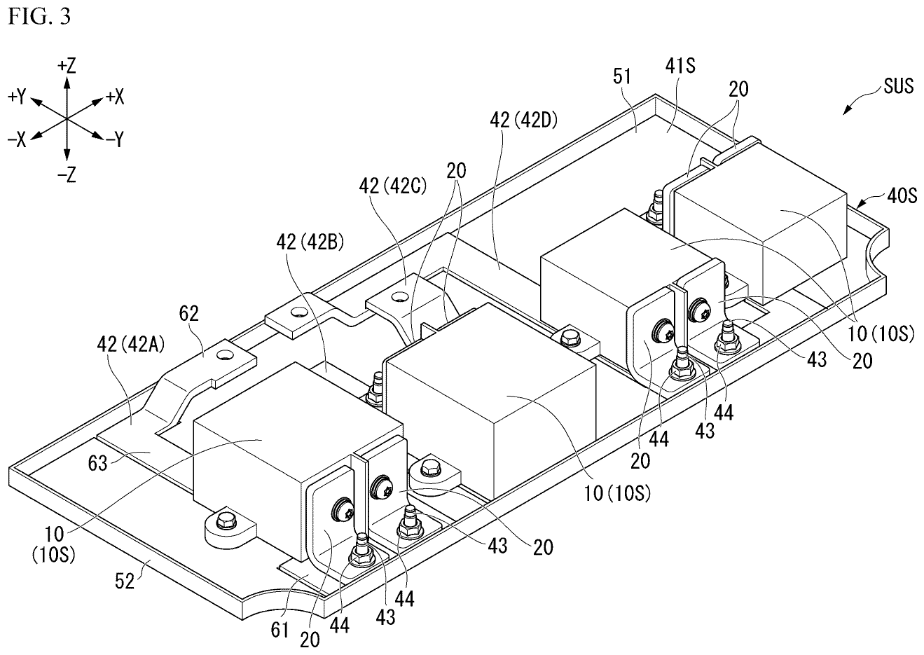

FIG. 3 is a perspective view for describing the subunit SUS. The subunit SUS includes, for example, a plurality of electronic components 10, a plurality of connection components 20, and a routing board 40S. The connection component 20 is a member forming an energization path in the vertical direction. The connection component 20 may be referred to as a “vertical routing member”.

### <4.1 Electronic Component>

First, the electronic component 10 will be described. The electronic component 10 is an electronic component mounted according to a function required for each subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. However, the type of the electronic component 10 is not limited to the above example. The electronic component 10 is, for example, a heat generating component that generates heat at the time of energization.

In the present embodiment, the plurality of electronic components 10 include an electronic component 10S that generates relatively large heat when energized. The electronic component 10S is a relay (for example, a mechanical relay or a semiconductor relay), a pyrofuse, a current sensor (for example, a current sensor having a shunt resistor), or the like. However, the type of the electronic component 10S is not limited to the above example.

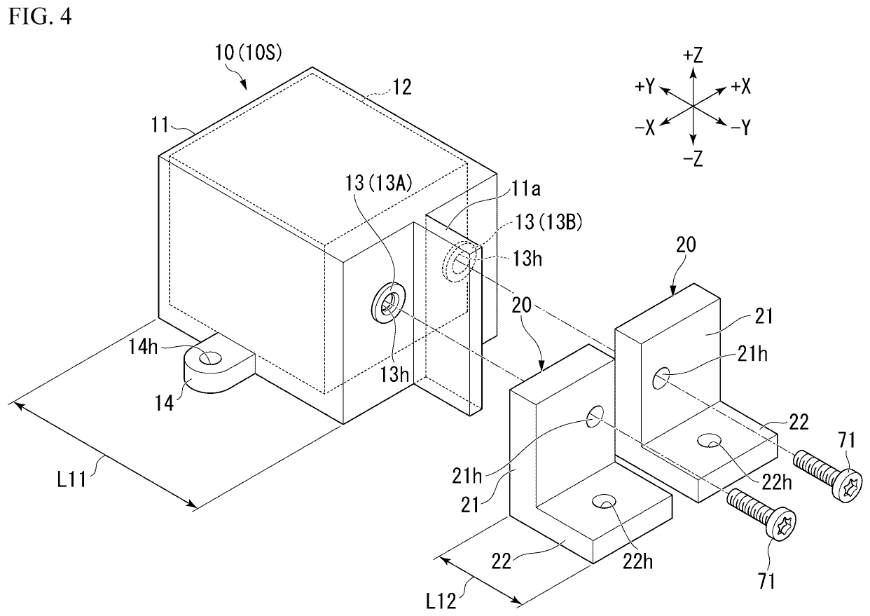

FIG. 4 is a perspective view illustrating the electronic component 10S and the connection component 20. The electronic component 10S is, for example, an electronic component in which a plurality of terminals 13 are disposed to be arranged at one end of the electronic component 10S. The electronic component 10S includes, for example, a case 11, a component body 12, a plurality of terminals 13, and a plurality of attachment portions 14.

### (Case)

The case 11 is an outer member that forms most of the outer shape of the electronic component 10S. The case 11 is made of, for example, synthetic resin and has an insulating property. The case 11 accommodates the component body 12. The case 11 and the component body 12 may be integrally formed.

In the present embodiment, the case 11 has an insulating rib 11a protruding in the horizontal direction (for example, the Y direction) and extending in the Z direction. The insulating rib 11a has, for example, a plate shape formed in the horizontal direction (for example, the Y direction) and the Z direction. The insulating rib 11a extends over the entire length of the case 11 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, a part of the insulating rib 11a is disposed between first portions 21 (that will be described later) of the two connection components 20 connected to the electronic component 10S. The insulating rib 11a electrically insulates between the first portions 21 of the two connection components 20 connected to the electronic component 10S.

### (Component Body)

The component body 12 is a portion that performs a main function of the electronic component 10S. For example, in a case where the electronic component 10S is a relay, the component body 12 includes a switch (for example, a contact) that switches between a conductive state and a non-conductive state. For example, in a case where the electronic component 10S is a fuse, the component body 12 includes a fusion portion that is fused when an overcurrent flows. For example, in a case where the electronic component 10S is a capacitor, the component body 12 includes a portion that accumulates electric charge.

### (Terminal)

The terminal 13 is an electrical connection portion exposed to the outside of the case 11. The terminal 13 is electrically connected to the component body 12 inside the case 11. In the present embodiment, the electronic component 10S includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side. One of the terminal 13A and the terminal 13B is an example of a “first terminal”. The other of the terminal 13A and the terminal 13B is an example of a “second terminal”.

In the present embodiment, the terminal 13A and the terminal 13B are provided at one end of the electronic component 10S in the horizontal direction (for example, the Y direction). The terminal 13A and the terminal 13B are disposed to be arranged in the horizontal direction (for example, the X direction). Each of the terminal 13A and the terminal 13B is directed in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the Y direction). An inner circumferential surface of the attachment hole 13h of the electronic component 10S has a screw groove.

### (Attachment Portion)

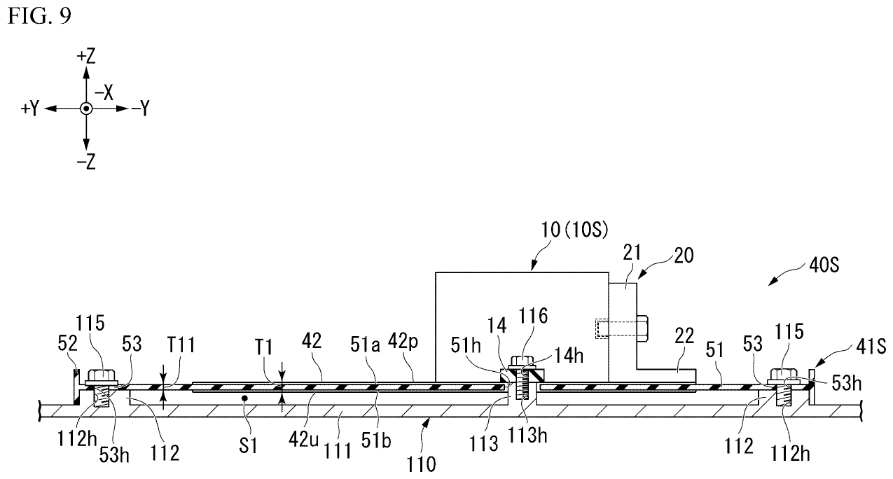

The attachment portion 14 is a portion for fixing the electronic component 10S. The attachment portion 14 has an attachment hole 14h to which a fastening member 116 (for example, a screw or a bolt; and see FIG. 9) that will be described later is attached. The attachment hole 14h is open in the Z direction. The attachment hole 14h is an insertion hole through which the fastening member 116 passes. A fixing destination of the attachment portion 14 will be described later.

### <4.2 Connection Component>

Next, the connection component 20 will be described. The connection component 20 is a component that electrically connects the electronic component 10S to the routing board 40S. The connection component 20 forms a part of an energization path in the subunit SUS. The connection component 20 is made of metal (for example, made of copper, made of a copper alloy, made of aluminum, or made of an aluminum alloy). The connection component 20 may be referred to as a “metal component”.

In the present embodiment, the connection component 20 electrically connects the electronic component 10S to the bus bar 42 (see FIG. 3) included in the routing board 40S. In the present embodiment, a length L12 of the connection component 20 in the longitudinal direction (for example, the Y direction) of the electronic component 10S is smaller than a length L11 of the electronic component 10S in the longitudinal direction. The connection component 20 includes, for example, a first portion 21 and a second portion 22.

### (First Portion)

The first portion 21 of the connection component 20 is a portion connected to the terminal 13 of the electronic component 10S. The first portion 21 is a plate-shaped or rectangular parallelepiped portion extending in the Z direction. The first portion 21 extends in the Z direction along one end (for example, an end in the Y direction) of the electronic component 10S. The first portion 21 is a standing portion that stands in the Z direction with respect to the routing board 40S (for example, with respect to a bus bar 42 that will be described later). The first portion 21 is adjacent to the electronic component 10S in the horizontal direction (for example, the Y direction). For example, the first portion 21 is adjacent to the terminal 13 of the electronic component 10S in the horizontal direction (for example, the Y direction), and is connected to the terminal 13 of the electronic component 10S from the horizontal direction (for example, the Y direction).

The first portion 21 of the connection component 20 has a first attachment hole 21h through which the fastening member 71 (for example, a screw or a bolt) passes. The first attachment hole 21h is open in the horizontal direction (for example, the Y direction). The fastening member 71 that has passed through the first attachment hole 21h is engaged with the attachment hole 13h of the terminal 13 of the electronic component 10S, and thus first portion 21 is physically and electrically connected to the terminal 13 of the electronic component 10S.

### (Second Portion)

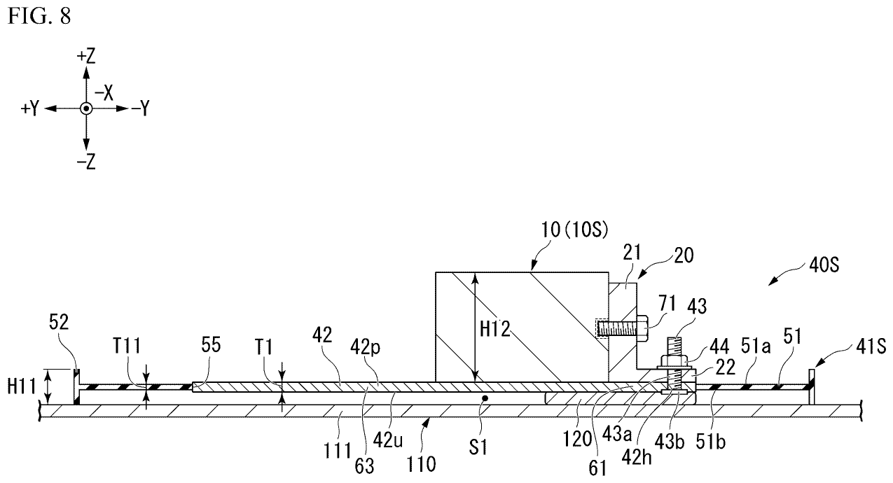

The second portion 22 of the connection component 20 is a portion connected to the bus bar 42 (see FIG. 3). The second portion 22 protrudes in the horizontal direction (for example, the Y direction) from the end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20 is attached to the fastening member 43 (for example, a screw or a bolt; and see FIG. 8) protruding from the bus bar 42 in the +Z direction from the Z direction, and is physically and electrically connected to the bus bar 42. In the present embodiment, the second portion 22 of the connection component 20 has a second attachment hole 22h through which the fastening member 43 passes. The second attachment hole 22h is open in the Z direction. In the second portion 22, the fastening member 43 passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42. In the present embodiment, the first portion 21 and the second portion 22 form one L-shaped connection component 20.

In the present embodiment, the bus bar 42 is disposed at a position away from the terminal 13 of the electronic component 10S (for example, a position away in the Z direction). The connection component 20 is disposed between the electronic component 10S and the bus bar 42. In the present disclosure, the phrase “the connection component is disposed between the electronic component and the bus bar” is not limited to a case where a part of the connection component is located between the electronic component and the bus bar when viewed from the X direction or the Y direction. The phrase “the connection component is disposed between the electronic component and the bus bar” may correspond to a case where a part of the connection component is located between the electronic component and the bus bar when viewed from a direction inclined with respect to the X direction or the Y direction. The connection component 20 electrically connects the terminal 13 of the electronic component 10S to the bus bar 42.

### <4.3 Routing Board>

Next, the routing board 40S will be described.

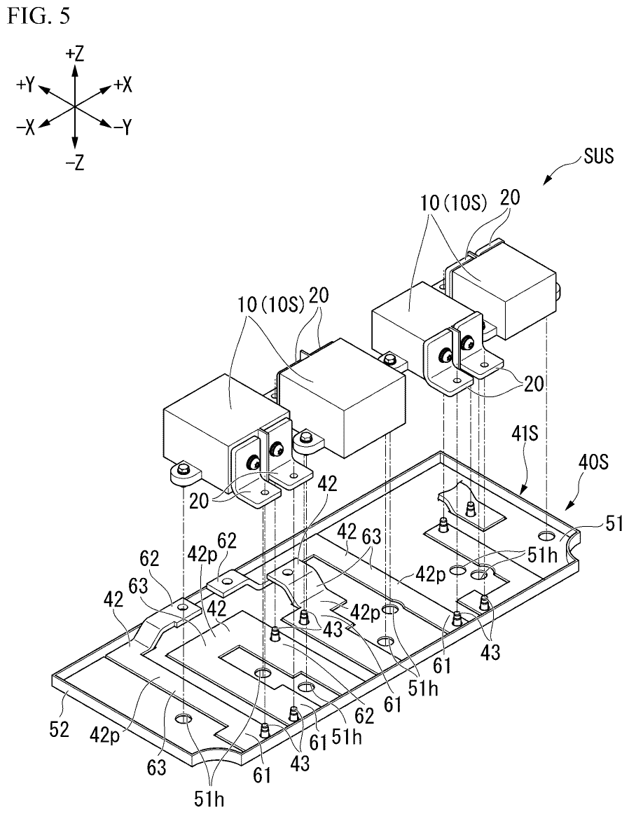

FIG. 5 is a perspective view for describing the routing board 40S. The routing board 40S is a member that forms at least a part of an energization path between a plurality of electronic components 10 (for example, a plurality of electronic components 10S) and/or at least a part of an energization path between the electronic component 10 (for example, the electronic component 10S) included in the subunit SUS and the electronic component 10 included in another subunit SU (for example, the subunit SUT). In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40S has a plate shape formed in the X direction and the Y direction.

The routing board 40S includes, for example, a base plate 41S, one or more (for example, a plurality of) bus bars 42, and a plurality of fastening members 43. In the present embodiment, the base plate 41S and the plurality of bus bars 42 are integrated through insert molding. For example, the routing board 40S is formed as one piece member by insert-molding the bus bar 42 with the base plate 41S after the fastening member 43 is fixed to the bus bar 42. That is, the bus bar 42 is integrated with the base plate 41S without using a fastening member such as a screw or a bolt. Note that the routing board 40S may be formed by using another structure instead of the insert molding. A modification example in which the routing board 40S is formed by using another structure will be described later.

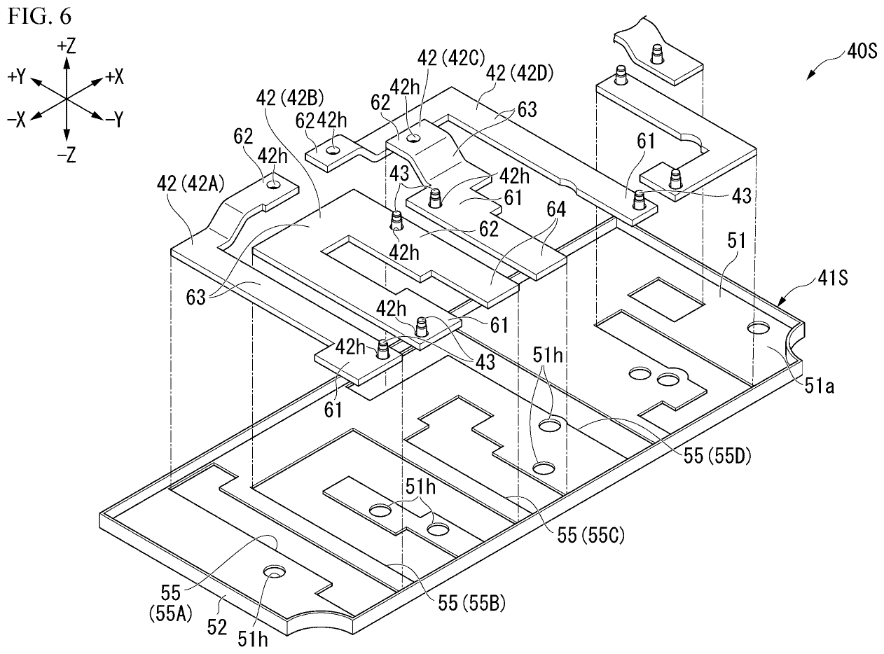

FIG. 6 is a partially exploded perspective view illustrating the routing board 40S. Hereinafter, for convenience of description, the base plate 41S, the bus bar 42, and the fastening member 43 will be described with reference to the drawings in which the routing board 40S is partially exploded.

### <4.3.1 Base Plate>

The base plate 41S is a support member that integrally supports the plurality of bus bars 42 arranged at intervals in the horizontal direction. The base plate 41S is made of, for example, a synthetic resin and has an insulating property. The base plate 41S electrically insulates the plurality of bus bars 42 from each other. The base plate 41S is an example of a “base member”. The base plate 41S may be referred to as an “insulating substrate”. The base plate 41S includes, for example, a flat surface portion 51, a frame portion 52, and a plurality of fixing portions 53 (see FIG. 9).

### (Flat Surface Portion)

The flat surface portion 51 is a portion formed in a plate shape in the base plate 41S. The flat surface portion 51 has a plate shape formed in the horizontal direction. The flat surface portion 51 forms a main portion of the base plate 41S. The flat surface portion 51 forms a base portion (insulating base portion) of the base plate 41S. In the present embodiment, the flat surface portion 51 extends over the entire width in the X direction of the base plate 41S and over the entire width in the Y direction of the base plate 41S except for the frame portion 52 of the base plate 41S.

The flat surface portion 51 has a first surface 51a and a second surface 51b (see FIG. 9). The first surface 51a is a surface directed in the +Z direction. The first surface 51a is a flat surface provided in the horizontal direction. The first surface 51a faces the plurality of electronic components 10 (for example, the plurality of electronic components 10S). The second surface 51b is located on the side opposite to the first surface 51a. The second surface 51b is a surface directed in the −Z direction. The second surface 51b is a flat surface provided in the horizontal direction. The second surface 51b faces the metal plate 110 (see FIG. 2). A thickness direction (plate thickness direction) of the flat surface portion 51 is the Z direction. In the present embodiment, a thickness T11 of the flat surface portion 51 in the Z direction is smaller than a thickness T1 of the bus bar 42 in the Z direction (for example, a thickness of a horizontal plate portion 42p that will be described later in the Z direction) (see FIG. 8). The thickness T11 of the flat surface portion 51 in the Z direction may be equal to the thickness T1 of the bus bar 42 in the Z direction, or may be larger than the thickness T1 of the bus bar 42 in the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where a part of the entire length of the accommodation portion 55 penetrates the flat surface portion 51 in the Z direction (for example, the remaining portion of the accommodation portion 55 may be a recess recessed in the Z direction, or may be provided inside the base plate 41S and not exposed to the outside of the base plate 41S). Similarly, in the present disclosure, the phrase “the accommodation portion is recessed in the first direction (Z direction)” may include a case where a part of the entire length of the accommodation portion 55 is recessed in the Z direction (for example, a remaining portion of the accommodation portion 55 may be a through-hole penetrating the flat surface portion 51 in the Z direction, or may be provided inside the base plate 41S and not exposed to the outside of the base plate 41S).

Each accommodation portion 55 has an outer shape corresponding to the shape of the bus bar 42 to be accommodated when viewed from the Z direction. The plurality of accommodation portions 55 include, for example, four accommodation portions 55A, 55B, 55C, and 55D. The accommodation portion 55A is provided to correspond to a bus bar 42A that will be described later, and accommodates at least a part of the bus bar 42A. The accommodation portion 55B is provided to correspond to a bus bar 42B that will be described later, and accommodates at least a part of the bus bar 42B. The accommodation portion 55C is provided to correspond to a bus bar 42C that will be described later, and accommodates at least a part of the bus bar 42C. The accommodation portion 55D is provided to correspond to a bus bar 42D that will be described later, and accommodates at least a part of the bus bar 42D.

### (Frame Portion)

The frame portion 52 is provided at a peripheral end of the base plate 41S. The frame portion 52 is a reinforcement rib protruding vertically from the end of the flat surface portion 51 (see FIG. 8). A width (thickness) H11 of the frame portion 52 in the Z direction is, for example, less than half of a width (thickness) H12 of the electronic component 10 in the Z direction (see FIG. 8). Note that the frame portion 52 may be omitted.

### (Fixing Portion)

The fixing portion 53 is a portion fixed to the metal plate 110 (see FIG. 9). The fixing portion 53 has an attachment hole 53h penetrating the base plate 41S in the Z direction. A fastening member 115 (for example, a screw or a bolt) that will be described later passes through the attachment hole 53h. This content will be described later.

### <4.3.2 Bus Bar>

The bus bar 42 is a routing member (electrical connection member) included in the routing board 40S. The bus bar 42 is, for example, a routing member for electrically connecting a plurality of electronic components (for example, a plurality of electronic components 10S). Alternatively, the bus bar 42 may be a routing member for electrically connecting the electronic component 10 (for example, the electronic component 10S) to the electronic component 10 included in another subunit SU (for example, the subunit SUT). The bus bar 42 is made of metal (for example, made of copper, made of a copper alloy, made of aluminum, or made of an aluminum alloy) and has conductivity. In the present embodiment, a plurality of bus bars 42, for example, four bus bars 42A, 42B, 42C, and 42D are included. The four bus bars 42A, 42B, 42C, and 42D are disposed to be arranged at intervals in the horizontal direction. The four bus bars 42A, 42B, 42C, and 42D include portions disposed on the same plane. The four bus bars 42A, 42B, 42C, and 42D are supported by the flat surface portion 51 of the base plate 41S. In the present disclosure, the phrase “the bus bar is supported by the flat surface portion” is not limited to the case where the bus bar 42 is accommodated in the accommodation portion 55, and may include a case where the bus bar 42 is attached to the first surface 51a or the second surface 51b of the flat surface portion 51.

At least a part of each bus bar 42 has a plate shape formed in the horizontal direction. At least a part of each bus bar 42 is accommodated in the accommodation portion 55 and extends along the flat surface portion 51. That is, at least a part of each bus bar 42 extends along the first surface 51a of the flat surface portion 51. At least a part of each bus bar 42 extends in the horizontal direction in the accommodation portion 55. Hereinafter, a portion of each bus bar 42 extending in a plate shape formed in the horizontal direction may be referred to as a “horizontal plate portion 42p”. The horizontal plate portion 42p is an example of a “plate portion”. The bus bar 42 is a member that forms a horizontal energization path. The bus bar 42 may be referred to as a “horizontal routing member”.

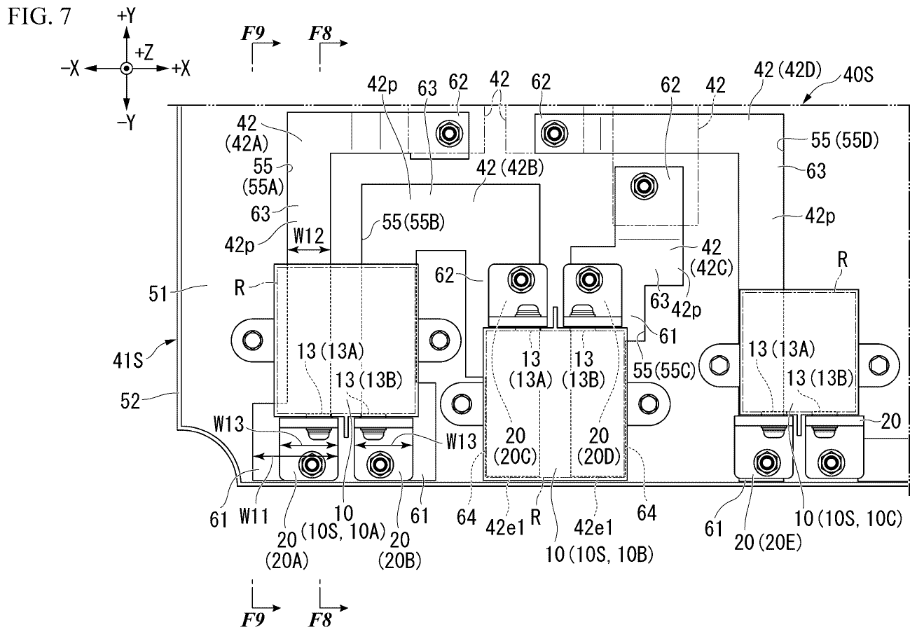

FIG. 7 is a plan view illustrating the subunit SUS. Each bus bar 42 includes, for example, a connection portion 61, a connection portion 62, and an extending portion 63.

The connection portion 61 is located in the middle of the bus bar 42 or at the first end of the bus bar 42. The connection portion 61 is a portion connected to the electronic component 10 (for example, the electronic component 10S) directly or via the connection component 20. The connection portion 61 includes, for example, a portion overlapping the connection component 20 when viewed from the Z direction. The connection portion 61 is adjacent to the connection component 20 in the Z direction and is connected to the connection component 20 from the Z direction. Instead of the above example, for example, the connection portion 61 may be adjacent to the terminal 13 of the electronic component 10 in the Z direction and directly connected to the terminal 13 of the electronic component 10 from the Z direction.

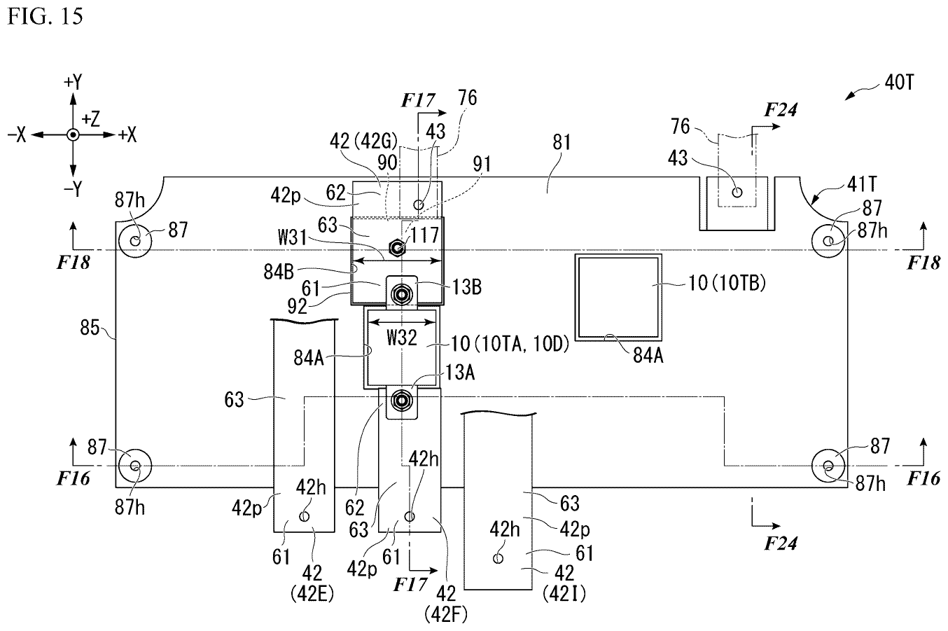

The connection portion 62 is located in the middle of the bus bar 42 or at the second end of the bus bar 42. The connection portion 62 is a portion connected to another electronic component 10 directly or via another connection component 20. Instead of the above example, the connection portion 62 may be connected to another bus bar 42 (for example, the bus bar 42 included in another subunit SU) or an external connection bus bar 76 (see FIG. 15).

The extending portion 63 extends from the connection portion 61 in the X direction or the Y direction. The extending portion 63 is provided between the connection portion 61 and the connection portion 62. The extending portion 63 extends over the connection portion 61 and the connection portion 62. The extending portion 63 connects the connection portion 61 to the connection portion 62.

In the present embodiment, the horizontal plate portion 42p described above includes at least the entire connection portion 61 and a part of the extending portion 63. That is, at least the entire connection portion 61 and a part of the extending portion 63 are accommodated in the accommodation portion 55 and located on the same plane.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends over the region R overlapping the electronic component 10 when viewed from the Z direction, over the −Y direction side and the +Y direction side of the region R. That is, the bus bar 42 is accommodated in the accommodation portion 55 to be easily routed through a better path (for example, a path with a shorter distance) without being disturbed by the presence of the electronic component 10.

One or more bus bars 42 may have an extension 64 in addition to the connection portion 61, the connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the connection portion 61 (or the connection portion 62). The extension 64 has a plate shape formed in the horizontal direction. The extension 64 is included in the horizontal plate portion 42p. The extension 64 is accommodated in the accommodation portion 55 and extends along the flat surface portion 51. The extension 64 extends to the region R overlapping the electronic component 10 when viewed from the Z direction, and has an end 42e1 of the bus bar 42 at a position overlapping the electronic component 10 when viewed from the Z direction.

Some routing examples of the bus bar 42 will be described below. The plurality of electronic components 10S includes three electronic components 10A, 10B, and 10C. The plurality of connection components 20 includes five connection components 20A, 20B, 20C, 20D, and 20E.

The bus bar 42A has the connection portion 61, the connection portion 62, and the extending portion 63. The connection portion 61 is connected to the terminal 13A of the electronic component 10A via the connection component 20A. The connection portion 62 is disposed at the end of the subunit SUS on the +Y direction side and is connected to the bus bar 42 included in another subunit SU. The extending portion 63 is accommodated in the accommodation portion 55 to extend over both sides of the region R through the region R overlapping the electronic component 10A when viewed from the Z direction.

The bus bar 42B has the connection portion 61, the connection portion 62, the extending portion 63, and the extension 64. The connection portion 61 is connected to the terminal 13B of the electronic component 10A via the connection component 20B. The connection portion 62 is connected to the terminal 13A of the electronic component 10B via the connection component 20C. The extension 64 extends to the region R overlapping the electronic component 10B when viewed from the Z direction, and has an end 42e1 of the bus bar 42 at a position overlapping the electronic component 10B.

The bus bar 42C has the connection portion 61, the second connection portion 62, and the extending portion 63. The connection portion 61 is connected to the terminal 13B of the electronic component 10B via the connection component 20D. The connection portion 62 is disposed at the end of the subunit SUS on the +Y direction side and is connected to the bus bar 42 included in another subunit SU.

The bus bar 42D has the connection portion 61, the connection portion 62, and the extending portion 63. The connection portion 61 is connected to the terminal 13A of the electronic component 10C via the connection component 20E. The connection portion 62 is disposed at the end of the subunit SUS on the +Y direction side and is connected to the bus bar 42 included in another subunit SU.

### (Exposure Structure on Upper Surface Side of Each Bus Bar

In the present embodiment, at least a part of the bus bar 42 is exposed to the upper surface side of the base plate 41S. For example, the connection portion 61, the connection portion 62, and the extending portion 63 of the bus bar 42 are exposed to the outside of the base plate 41S on the upper surface side (the first surface 51a side of the flat surface portion 51) of the base plate 41S. For example, the extending portion 63 of the bus bar 42 is exposed to the outside of the base plate 41S on the upper surface side of the base plate 41S at least over the entire length between the connection portion 61 and the connection portion 62.

### (Exposure Structure on Lower Surface Side of Each Bus Bar)

In the present embodiment, at least a part of the bus bar 42 is exposed to the lower surface side of the base plate 41S. For example, the entire connection portion 61 and at least a part of the extending portion 63 are exposed to the outside of the base plate 41S on the lower surface side of the base plate 41S (the second surface 51b side of the flat surface portion 51). In the present embodiment, a gap S1 is formed between the flat surface portion 51 of the base plate 41S and the metal plate 110 (see FIG. 8). The bus bar 42 includes an exposed portion 42u exposed to the gap S1 (see FIG. 8). The exposed portion 42u includes, for example, the entire connection portion 61 and at least a part of extending portion 63.

### <4.3.3 Fastening Member>

Next, the fastening member 43 will be described.

FIG. 8 is a cross-sectional view taken along line F8-F8 of the structure illustrated in FIG. 7. The fastening member 43 is a component for fixing the bus bar 42 to the connection component 20 corresponding to the bus bar 42. The fastening member 43 is, for example, a caulking bolt fixed to the bus bar 42. The fastening member 43 is an example of a “fastening portion”.

In the present embodiment, at least one of the connection portion 61 and the connection portion 62 of the bus bar 42 has a through-hole 42h. The through-hole 42h penetrates the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 42h of the bus bar 42. With this fixation, the fastening member 43 is electrically and physically connected to the bus bar 42 in a state in which the shaft 43a protrudes in the +Z direction from the through-hole 42h of the bus bar 42. The fastening member 43 is not limited to caulking fixation, and may be fixed to the bus bar 42 through welding or other methods.

In the present embodiment, the connection component 20 is attached to the fastening member 43 from the Z direction in a state of being previously fixed to the electronic component 10 via the fastening member 71. For example, in the connection component 20, the shaft 43a of the fastening member 43 is inserted into the second attachment hole 22h of the second portion 22. The engagement member 44 (for example, a nut) is engaged with the shaft 43a of the fastening member 43 protruding from the second attachment hole 22h of the second portion 22 of the connection component 20.

The engagement member 44 is attached to the shaft 43a in the Z direction. This engagement fixes the second portion 22 of the connection component 20 to the fastening member 43.

### (Heat Transfer Member)

First, the heat transfer member 120 will be described.

The heat transfer member 120 is a member for transferring heat generated by the electronic component 10 (for example, the electronic component 10S) at the time of energization and/or heat (Joule heat) generated by the bus bar 42 itself at the time of energization to the metal plate 110. The heat transfer member 120 is, for example, a heat transfer sheet (for example, a thermally conductive silicone sheet) having elasticity. The heat transfer member 120 is made of a material having a higher thermal conductivity than the base plate 41S (or the base member 41T that will be described later), for example. However, the heat transfer member 120 is not limited to the above example, and may be a heat transfer member formed of a thermally conductive gel or another material. In the present embodiment, the heat transfer member 120 has an insulating property.

In the present embodiment, the heat transfer member 120 is partially provided in the routing board 40S (see FIG. 2). For example, the heat transfer member 120 is disposed at a position overlapping a part of the bus bar 42 when viewed from the Z direction. The heat transfer member 120 is disposed between the bus bar 42 and a flat surface portion 111 of the metal plate 110 that will be described later. For example, the heat transfer member 120 is disposed between the exposed portion 42u of the bus bar 42 and the flat surface portion 111 of the metal plate 110, and is in contact with the exposed portion 42u of the bus bar 42 and the flat surface portion 111 of the metal plate 110. The heat transfer member 120 transfers heat transferred from the electronic component 10 (for example, the electronic component 10S) to the bus bar 42 and/or heat generated by the bus bar 42 from the bus bar 42 to the flat surface portion 111 of the metal plate 110.

In the present embodiment, the heat transfer member 120 is disposed at a position overlapping a part of the bus bar 42 in the vicinity of the electronic component 10 (for example, the electronic component 10S) when viewed from the Z direction. In the present embodiment, the heat transfer member 120 is disposed at a position overlapping the connection component 20 when viewed from the Z direction. In other words, the heat transfer member 120 is disposed at a position overlapping the connection portion 61 or the connection portion 62 of the bus bar 42 when viewed from the Z direction. The heat transfer member 120 transfers heat transferred from the electronic component 10S to the bus bar 42 via the connection component 20 from the bus bar 42 to the flat surface portion 111 of the metal plate 110.

### <4.4 Fixing Structure of Routing Board and Electronic Component>

Next, a fixing structure of the routing board 40S and the electronic component 10 will be described.

FIG. 9 is a cross-sectional view taken along line F9-F9 of the structure illustrated in FIG. 7. The metal plate 110 includes, for example, a fixing portion 112 and a fixing portion 113 in addition to a flat surface portion 111 that will be described later.

The fixing portion 112 is a fixing portion for fixing the base plate 41S to the metal plate 110. The fixing portion 112 is provided at a position corresponding to the fixing portion 53 of the base plate 41S when viewed from the Z direction. The fixing portion 112 is a cylindrical or prismatic boss protruding in the +Z direction from the flat surface portion 111 of the metal plate 110. The fixing portion 112 has an engagement hole 112h that is open in the +Z direction. An inner circumferential surface of the engagement hole 112h has a screw groove.

As described above, the fixing portion 53 of the base plate 41S has an attachment hole 53h. A fastening member 115 (for example, a screw or a bolt) passes through the attachment hole 53h. When the fastening member 115 that has passed through the attachment hole 53h of the fixing portion 53 of the base plate 41S is engaged with the engagement hole 112h of the fixing portion 112 of the metal plate 110, the base plate 41S is fixed to the metal plate 110.

The fixing portion 113 is a fixing portion for directly fixing the electronic component 10 (for example, the electronic component 10S) to the metal plate 110 without the base plate 41S interposed therebetween. The fixing portion 113 is provided at a position corresponding to the attachment portion 14 of the electronic component 10 when viewed from the Z direction. The fixing portion 113 is a cylindrical or prismatic boss protruding in the +Z direction from the flat surface portion 111. The fixing portion 113 has an engagement hole 113h that is open in the +Z direction. An inner circumferential surface of the engagement hole 113h has a screw groove.

In the present embodiment, the flat surface portion 51 of the base plate 41S has a through-hole 51h. The through-hole 51h penetrates the flat surface portion 51 in the Z direction. The through-hole 51h is provided at a position corresponding to the fixing portion 113 of the metal plate 110 when viewed from the Z direction. The fixing portion 113 of the metal plate 110 passes through the through-hole 51h of the base plate 41S and protrudes to the same position as the first surface 51a of the flat surface portion 51 or further toward the +Z direction side than the first surface 51a of the flat surface portion 51. The attachment portion 14 of the electronic component 10 is in contact with the fixing portion 113 at the same position as the first surface 51a of the flat surface portion 51 or at a position located further toward the +Z direction side than the first surface 51a of the flat surface portion 51.

A fastening member 116 (for example, a screw or a bolt) passes through the attachment hole 14h of the attachment portion 14 of the electronic component 10 from the +Z direction side. When the fastening member 116 that has passed through the attachment hole 14h of the attachment portion 14 of the electronic component 10 is engaged with the engagement hole 113h of the fixing portion 113 of the metal plate 110, the electronic component 10 is fixed to the metal plate 110 without the base plate 41S interposed therebetween. Note that, instead of the above-described example, the electronic component 10 may be fixed to a fixing portion provided in the base plate 41S.

### <5. Shape Example of Bus Bar>

Next, a shape example of the bus bar 42 will be described.

### <5.1 First Shape Example of Bus Bar>

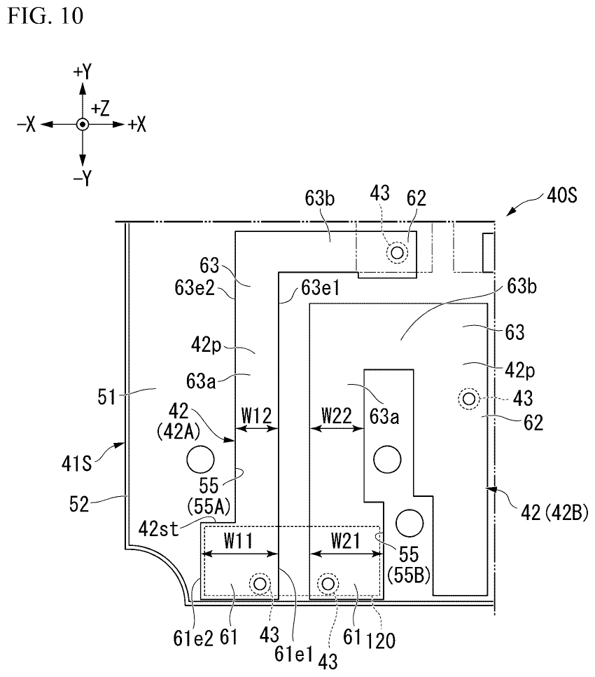

FIG. 10 is a plan view for describing a first shape example of the bus bar 42. In the present embodiment, the bus bar 42A is an example of a “first bus bar”. The connection portion 61 of the bus bar 42A is an example of a “first connection portion”. The extending portion 63 of the bus bar 42A includes a first straight portion 63a extending in the Y direction from the connection portion 61 of the bus bar 42A and a second straight portion 63b bent from the first straight portion 63a and extending in the X direction. The first straight portion 63a of the bus bar 42A is an example of a “first extending portion”. The connection component 20A is an example of a “first connection component”.

A width W11 of the connection portion 61 of the bus bar 42A in the X direction is larger than a width W12 of the extending portion 63 of the bus bar 42A in the X direction (for example, the width W12 of the first straight portion 63a in the X direction). In the present embodiment, the connection portion 61 and the first straight portion 63a of the extending portion 63 are accommodated in the accommodation portion 55. Inside the accommodation portion 55, the width W11 of the connection portion 61 of the bus bar 42A in the X direction is larger than the width W12 of the extending portion 63 of the bus bar 42A in the X direction. The width W11 is, for example, the minimum width of the connection portion 61 in the X direction. The width W12 is, for example, the minimum width of the extending portion 63 in the X direction (for example, the minimum width of the first straight portion 63a in the X direction).

In the present embodiment, the width W12 (for example, the width W12 of the first straight portion 63a in the X direction) of the extending portion 63 of the bus bar 42A in the X direction is equal to or smaller than a width W13 (see FIG. 7) of the connection component 20A in the X direction. On the other hand, the width W11 of the connection portion 61 in the X direction is larger than the width W13 of the connection component 20A in the X direction. The width W13 is, for example, the minimum width of the connection component 20A in the X direction.

The connection portion 61 has an edge 61e1 extending in the Y direction and an edge 61e2 located on the side opposite to the edge 61e1 in the X direction and extending in the Y direction. The edge 61e1 is an example of a “first edge”. The edge 61e2 is an example of a “second edge”.

The extending portion 63 (for example, the first straight portion 63a) has an edge 63e1 extending in the Y direction and an edge 63e2 located on the side opposite to the edge 63e1 in the X direction and extending in the Y direction. The edge 63e1 is an example of a “third edge”. The edge 63e2 is an example of a “fourth edge”.

In the present embodiment, the edge 61e1 of the connection portion 61 and the edge 63e1 of the extending portion 63 are linearly continuous in the Y direction. On the other hand, a step 42st in the X direction exists between the edge 61e2 of the connection portion 61 and the edge 63e2 of the extending portion 63.

In the present embodiment, the bus bar 42B is an example of a “second bus bar”. The connection portion 61 of the bus bar 42B is an example of a “second connection portion”. The extending portion 63 of the bus bar 42B includes a first straight portion 63a extending in the Y direction from the connection portion 61 of the bus bar 42B and a second straight portion 63b bent from the first straight portion 63a and extending in the X direction. The first straight portion 63a of the extending portion 63 of the bus bar 42B is an example of a “second extending portion”. The connection component 20B is an example of a “second connection component”.

In the present embodiment, a width W21 of the connection portion 61 of the bus bar 42B in the X direction is larger than a width W22 of the extending portion 63 of the bus bar 42B in the X direction (for example, the width W22 of the first straight portion 63a in the X direction). In the present embodiment, the connection portion 61 and the first straight portion 63a of the extending portion 63 are accommodated in the accommodation portion 55. Inside the accommodation portion 55, the width W21 of the connection portion 61 of the bus bar 42B in the X direction is larger than the width W22 of the extending portion 63 of the bus bar 42B in the X direction. The width W21 is, for example, the minimum width of the connection portion 61 in the X direction. The width W22 is, for example, the minimum width of the extending portion 63 in the X direction (for example, the minimum width of the first straight portion 63a in the X direction).

As illustrated in FIG. 10, the connection portion 61 of the bus bar 42A and the connection portion 61 of the bus bar 42A are adjacent to each other in the X direction. The first straight portion 63a of the extending portion 63 of the bus bar 42A and the first straight portion 63a of the extending portion 63 of the bus bar 42B are adjacent to each other in the X direction. In the present embodiment, the connection portion 61 of the bus bar 42A protrudes to the side opposite to the bus bar 42B (−X direction side) with respect to the first straight portion 63a of the extending portion 63 of the bus bar 42A. On the other hand, the connection portion 61 of the bus bar 42B protrudes to the side opposite to the bus bar 42A (+X direction side) with respect to the first straight portion 63a of the extending portion 63 of the bus bar 42B.

In the present embodiment, the width W11 of the connection portion 61 of the bus bar 42A in the X direction and the width W21 of the connection portion 61 of the bus bar 42B in the X direction are the same. On the other hand, the width W12 of the extending portion 63 of the bus bar 42A in the X direction is smaller than the width W22 of the extending portion 63 of the bus bar 42B in the X direction. The bus bar 42B has, for example, a larger heat dissipation property or heat storage property than the bus bar 42A.

In the present embodiment, the heat transfer member 120 has a size over the connection portion 61 of the bus bar 42A and the connection portion 61 of the bus bar 42B. For example, the heat transfer member 120 overlaps the connection portion 61 of the bus bar 42A and the connection portion 61 of the bus bar 42B when viewed from the Z direction. The heat transfer member 120 thermally connects the bus bar 42A to the bus bar 42B. Therefore, in a case where the temperature of the bus bar 42B is lower than the temperature of the bus bar 42A, part of the heat of the bus bar 42A moves to the bus bar 42B via the heat transfer member 120. According to such a constitution, the heat dissipation property of the electrical connection unit 1 can be further improved through heat equalization of the plurality of bus bars 42.

### <5.2 Second Shape Example of Bus Bar>

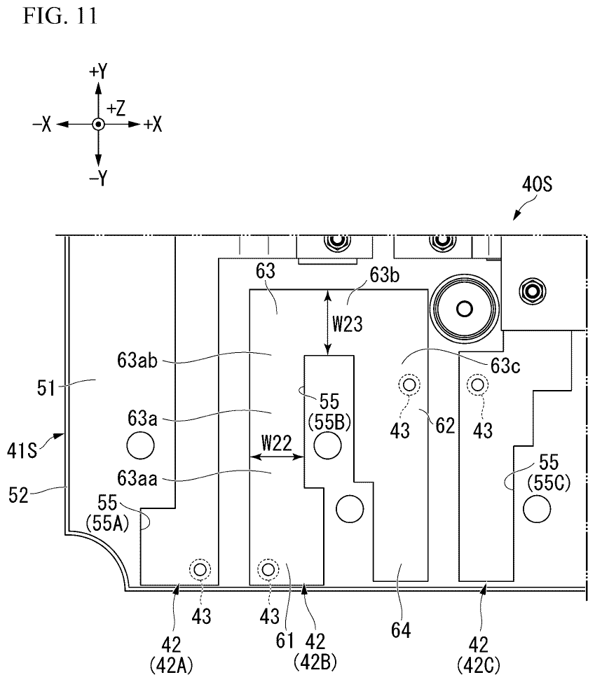

FIG. 11 is a plan view for describing a second shape example of the bus bar 42. In the present embodiment, the electronic component 10A is an example of a “first electronic component”. The electronic component 10B is an example of a “second electronic component”. The connection portion 61 of the bus bar 42B is an example of a “first connection portion”. The connection portion 62 of the bus bar 42B is an example of a “second connection portion”. In the present embodiment, the extending portion 63 of the bus bar 42B includes, for example, a first straight portion 63a, a second straight portion 63b, and a third straight portion 63c.

The first straight portion 63a extends from the connection portion 61 in a direction different from the direction from the connection portion 61 of the bus bar 42B toward the connection portion 62 at the shortest distance. The first straight portion 63a extends, for example, in the Y direction. The first straight portion 63a is an example of a “first extending portion”.

The first straight portion 63a includes a first end (first portion) 63aa connected to the connection portion 61 and a second end (second portion) 63ab located on a side opposite to the first end 63aa. For example, the first end 63aa is located on the −Y direction side with respect to the connection portion 62 in the extending direction (Y direction) of the first straight portion 63a. On the other hand, the second end 63ab is located on the side opposite (+Y direction side) to the first end 63aa with respect to the connection portion 62 in the extending direction (Y direction) of the first straight portion 63a.

In the present embodiment, at least a part of the first straight portion 63a overlaps the electronic component 10A in the Z direction. For example, the first straight portion 63a extends over the region R overlapping the electronic component 10A when viewed from the Z direction, over the −Y direction side and the +Y direction side of the region R.

The second straight portion 63b extends from the second end 63ab of the first straight portion 63a in a direction approaching the connection portion 62. However, for example, the second straight portion 63b extends from the second end 63ab in a direction different from the direction from the second end 63ab of the first straight portion 63a toward the connection portion 62 of the bus bar 42B at the shortest distance. For example, the second straight portion 63b is bent from the first straight portion 63a and extends in the X direction. The second straight portion 63b is an example of a “second extending portion”. The second straight portion 63b does not overlap any electronic component 10 when viewed from the Z direction.

The third straight portion 63c extends from the second straight portion 63b toward the connection portion 62 of the bus bar 42B. The third straight portion 63c extends, for example, in the Y direction. In other words, the third straight portion 63c extends in parallel with the first straight portion 63a. The third straight portion 63c is an example of a “third extending portion”.

In the present embodiment, the connection portion 61, the connection portion 62, the first straight portion 63a, the second straight portion 63b, and the third straight portion 63c of the bus bar 42B are included in the horizontal plate portion 42p and located on the same plane. The connection portion 61, the connection portion 62, the first straight portion 63a, the second straight portion 63b, and the third straight portion 63c of the bus bar 42B are accommodated in, for example, the accommodation portion 55.

In the present embodiment, a width W23 of the second straight portion 63b of the bus bar 42B in the Y direction is larger than a width W22 of the first straight portion 63a of the bus bar 42B in the X direction. The width W22 is, for example, a width in the X direction of a portion of the bus bar 42B located in the region R overlapping the electronic component 10A when viewed from the Z direction. The width W22 is, for example, the minimum width of the first straight portion 63a in the X direction. The width W23 is, for example, the minimum width of the second straight portion 63b in the Y direction.

In the present embodiment, at least a part (for example, the whole) of the first straight portion 63a and at least a part (for example, the whole) of the second straight portion 63b are accommodated in the accommodation portion 55. Inside the accommodation portion 55, the width W23 of the second straight portion 63b in the Y direction is larger than the width W22 of the first straight portion 63a in the X direction.

From another point of view, in the present embodiment, the width W23 of the second straight portion 63b of the bus bar 42B in the Y direction is larger than the width W13 (see FIG. 7) of the connection component 20B in the X direction.

### <6. Constitution of Subunit SUT>

Next, a constitution of the subunit SUT will be described.

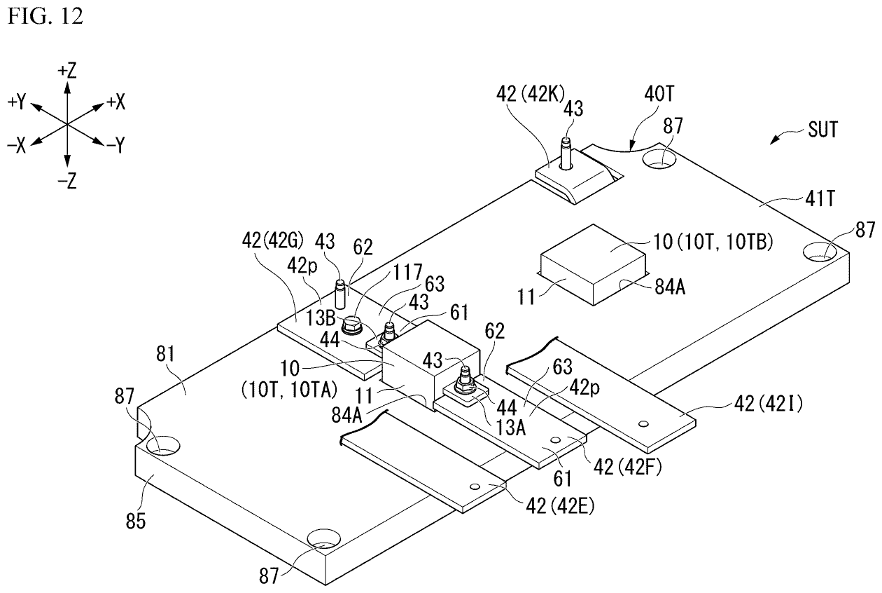

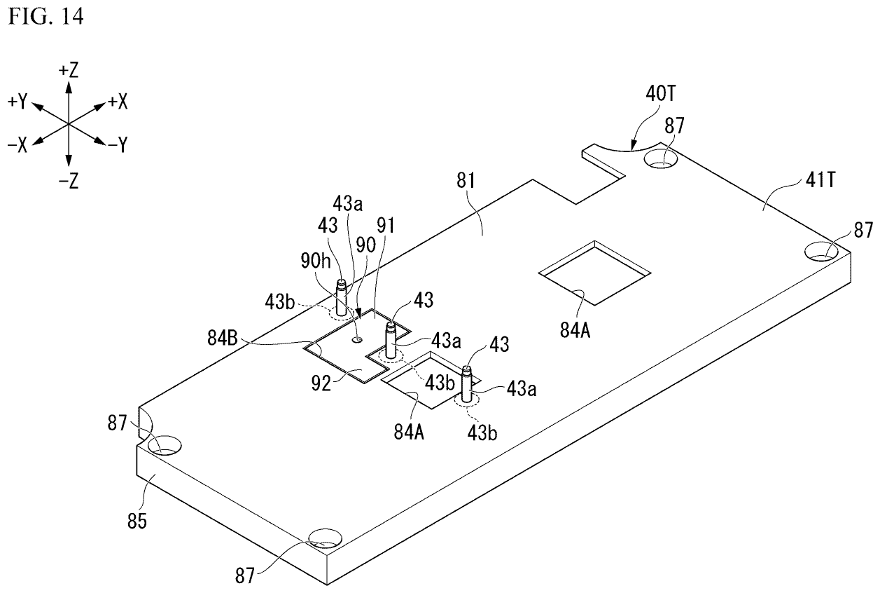

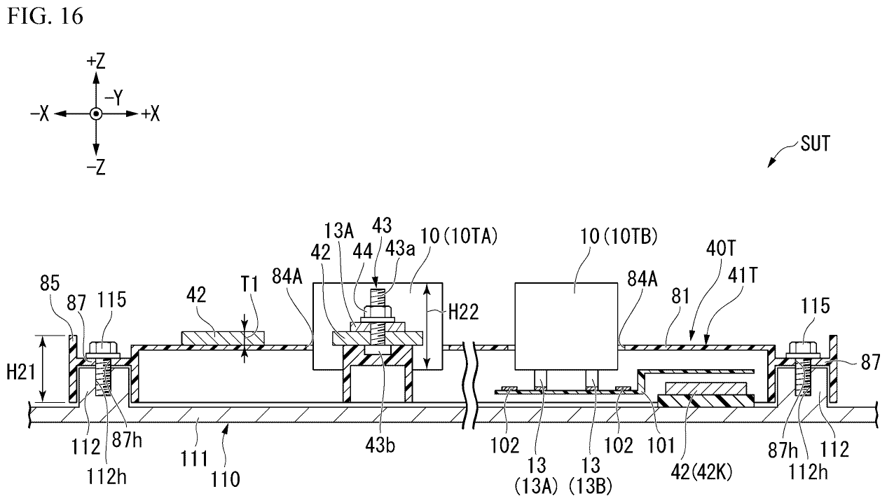

FIG. 12 is a perspective view illustrating the subunit SUT. The subunit SUT includes, for example, a plurality of electronic components 10, a routing structure 40T, an auxiliary base member 101 (see FIG. 16), and a metal portion 90 (see FIG. 14).

### <6.1 Electronic Component>

First, the electronic component 10 will be described. The plurality of electronic components 10 include a plurality of electronic components 10TA (only one is illustrated in FIG. 12) and a plurality of electronic components 10TB (only one is illustrated in FIG. 12). Note that the plurality of electronic components 10 may include only one of the electronic component 10TA and the electronic component 10TB.

The electronic component 10TA is an example of the electronic component 10T described above. The electronic component 10TA is an electronic component having a smaller amount of heat generation than the electronic component 10S when energized. On the other hand, the electronic component 10TB is another example of the electronic component 10T described above. The electronic component 10TB is an electronic component having a lower mountability (for example, requiring a complicated implementation structure) than the electronic component 10S. The electronic component 10TB has, for example, a terminal 13 protruding in the −Z direction toward the flat surface portion 111 of the metal plate 110 (see FIG. 16). For example, the electronic component 10TB has a smaller amount of heat generation than the electronic component 10S when energized.

Hereinafter, in a case where the electronic component 10TA and the electronic component 10TB are not distinguished, the electronic components are simply referred to as “electronic component 10T”. The electronic component 10T is, for example, a connector, a fuse, a capacitor, a branch component, any of various sensors (for example, a current sensor or a voltage sensor), an electronic control unit, or an electronic component unit in which two or more of these are unitized. However, the type of the electronic component 10T is not limited to the above example.

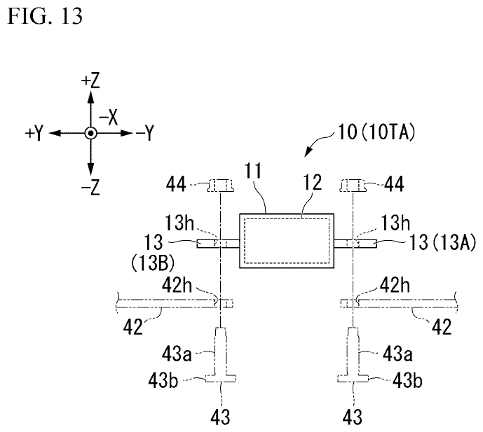

FIG. 13 is a front view illustrating the electronic component 10TA. The electronic component 10TA is, for example, an electronic component in which a plurality of terminals 13 are separately disposed at both ends of the electronic component 10TA in the horizontal direction. In the present embodiment, the terminal 13A and the terminal 13B are disposed separately at both ends of the electronic component 10TA in the Y direction. The terminals 13A and 13B protrude in the horizontal direction (for example, the +Y direction or the −Y direction) from the center of the case 11 in the Z direction. Each terminal 13 has an attachment hole 13h through which a fastening member 43 (for example, a screw or a bolt) passes. The attachment hole 13h is open in the Z direction.

### <6.2 Routing Structure>

Next, referring to FIG. 12 again, the routing structure 40T will be described. The routing structure 40T is a member that forms at least a part of an energization path between the plurality of electronic components 10 (for example, the plurality of electronic components 10T) and/or at least a part of an energization path between the electronic component 10 (for example, the electronic component 10T) included in the subunit SUT and the electronic component 10 included in another subunit SU (for example, the subunit SUS). The routing structure 40T includes, for example, a base member 41T, one or more (for example, a plurality of) bus bars 42, and a plurality of fastening members 43. Note that the content of the fastening member 43 is similar to that of the fastening member 43 described in the subunit SUS, and thus repeated description will be omitted.

### <6.2.1 Base Member>

FIG. 14 is a perspective view illustrating the base member 41T. The base member 41T is a support member that integrally supports the plurality of bus bars 42 arranged at intervals in the horizontal direction. The base member 41T is made of, for example, a synthetic resin and has an insulating property. The base member 41T electrically insulates the plurality of bus bars 42 from each other by using, for example, a rib (not illustrated). The base member 41T may be referred to as an “insulating substrate”. The base member 41T has a three-dimensional structure thicker in the Z direction than the base plate 41S included in the subunit SUS. The base member 41T includes, for example, a support wall 81, a frame portion 85 (peripheral wall portion), and a fixing portion 87.

### (Support Wall)

The support wall 81 is, for example, a plate-shaped wall portion provided in the horizontal direction. The plurality of bus bars 42 are disposed on the support wall 81 and are supported from below by the support wall 81 (see FIG. 12). The support wall 81 that supports the bus bar 42 is not limited to a wall portion provided in the horizontal direction, and may be a grid-shaped wall portion formed by a plurality of ribs extending in the Z direction. In the present embodiment, the fastening member 43 is attached to the support wall 81. The fastening member 43 protrudes from the support wall 81 in the +Z direction.

### (Accommodation Portion Accommodating Electronic Component)

In the present embodiment, the base member 41T has an accommodation portion 84A that is open to the +Z direction side. The accommodation portion 84A is, for example, a recess in which a part of the support wall 81 is recessed in the Z direction or a through-hole penetrating the support wall 81 in the Z direction. The accommodation portion 84A has an outer shape corresponding to the shape of the case 11 (that is, the component body 12) of the electronic component 10 (for example, the electronic component 10T) when viewed from the Z direction. At least a part of the electronic component 10 (for example, the electronic component 10T) (for example, at least a part of the component body 12) is accommodated in the accommodation portion 84A. At least a part of the electronic component 10 accommodated in the accommodation portion 84A is located on the −Z direction side compared with the support wall 81.

### (Accommodation Portion Accommodating Metal Portion)

In the present embodiment, the base member 41T has an accommodation portion 84B that is open to the +Z direction side. The accommodation portion 84B is, for example, a recess in which a part of the support wall 81 is recessed in the Z direction or a through-hole penetrating the support wall 81 in the Z direction. The accommodation portion 84B has an outer shape corresponding to the shape of the metal portion 90 that will be described later when viewed from the Z direction. At least a part of the metal portion 90 is accommodated in the accommodation portion 84B. At least a part of the metal portion 90 accommodated in the accommodation portion 84B is located on the −Z direction side compared with the support wall 81.

### (Frame Portion)

The frame portion 85 is provided at a peripheral end of the base member 41T. The frame portion 85 is a rib (peripheral wall portion) extending in the Z direction at the peripheral end of the base member 41T. A width (thickness) H21 of the frame portion 85 (peripheral wall portion) in the Z direction is, for example, half or more of a width (thickness) H22 of the electronic component 10 (for example, the electronic component 10TA) in the Z direction (see FIG. 16). Note that the frame portion 85 may be omitted.

### (Fixing Portion)

The fixing portion 87 is a portion fixed to the metal plate 110 (see FIG. 16). The fixing portion 87 faces the fixing portion 112 of the metal plate 110 in the Z direction. The fixing portion 87 has an attachment hole 87h penetrating the base member 41T in the Z direction. A fastening member 115 (for example, a screw or a bolt) passes through the attachment hole 87h. When the fastening member 115 that has passed through the attachment hole 87h is engaged with the engagement hole 112h of the fixing portion 112 of the metal plate 110, the base member 41T is fixed to the metal plate 110.

### <6.2.2 Bus Bar>

Next, the bus bar 42 included in the routing structure 40T will be described.

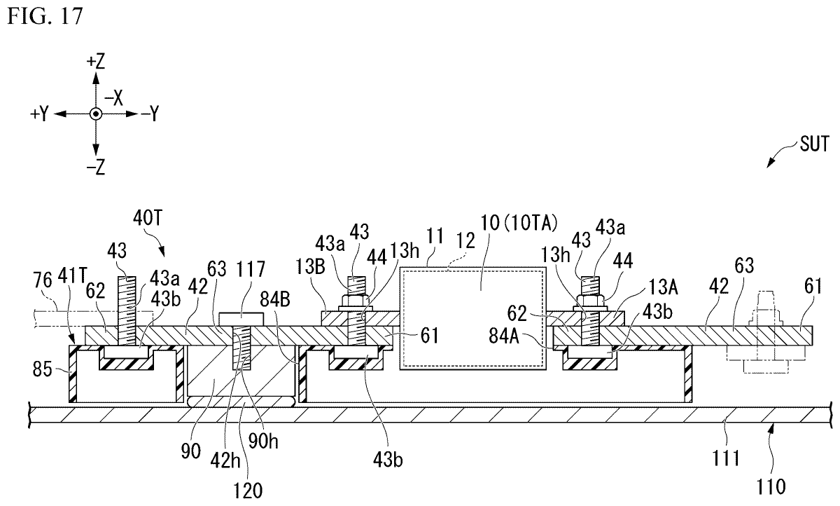

FIG. 15 is a plan view illustrating the subunit SUT. The bus bar 42 is a routing member (electrical connection member) included in the routing structure 40T. The bus bar 42 is, for example, a routing member for electrically connecting a plurality of electronic components 10 (for example, a plurality of electronic components 10T). Alternatively, the bus bar 42 may be a routing member for connecting the electronic component 10 (for example, the electronic component 10T) to the electronic component 10 included in another subunit SU (for example, the subunit SUS). In the present embodiment, the plurality of bus bars 42 are supported from below by the base member 41T and are disposed at positions away from the metal plate 110. The bus bar 42 is disposed immediately below the terminal 13 of the electronic component 10, for example. The bus bar 42 overlaps the component body 12 of the electronic component 10 when viewed from the X direction or the Y direction (see FIG. 17).

The plurality of bus bars 42 include, for example, four bus bars 42E, 42F, 42G, and 42I. The four bus bars 42E, 42F, 42G, and 42I are disposed to be arranged at intervals in the horizontal direction. The four bus bars 42E, 42F, 42G, and 42I include portions disposed on the same plane. At least a part of each bus bar 42 is the horizontal plate portion 42p. In the present embodiment, each bus bar 42 has a plate shape formed in the horizontal direction over the entire length. The horizontal plate portion 42p of each bus bar 42 includes the connection portion 61, the connection portion 62, and the extending portion 63. In the present embodiment, the subunit SUT includes an electronic component 10D as one of the electronic components 10TA.

The connection portion 61 of the bus bar 42E is connected to the bus bar 42 included in the subunit SUS. Similarly, the connection portion 61 of the bus bar 42F is connected to the bus bar 42 included in the subunit SUS. The connection portion 62 of the bus bar 42F is physically and electrically connected to the terminal 13A of the electronic component 10D. For example, the terminal 13A of the electronic component 10D is placed on the horizontal plate portion 42p of the bus bar 42F to be connected to the connection portion 62 of the bus bar 42F.

The connection portion 61 of the bus bar 42G is physically and electrically connected to the terminal 13B of the electronic component 10D. For example, the terminal 13B of the electronic component 10D is placed on the horizontal plate portion 42p of the bus bar 42G to be connected to the connection portion 61 of the bus bar 42G. The connection portion 61 of the bus bar 42G is an example of a “first connection portion”. The connection portion 62 of the bus bar 42G is physically and electrically connected to the external connection bus bar 76. The connection portion 62 of the bus bar 42G is connected to an external device via the bus bar 76. The connection portion 62 of the bus bar 42G is an example of a “second connection portion”. The bus bar 76 is an example of an “external connection component”. Note that the connection portion 62 of the bus bar 42G may be physically and electrically connected to the terminal 13 of another electronic component 10 instead of the bus bar 76.

The connection portion 61 of the bus bar 42I is connected to the bus bar 42 included in the subunit SUS. The connection portion 62 of the bus bar 421 is physically and electrically connected to the terminal 13A of the electronic component 10T (not illustrated).

### <6.3 Auxiliary Base Member>

Next, the auxiliary base member 101 will be described.

FIG. 16 is a cross-sectional view taken along line F16-F16 of the structure illustrated in FIG. 15. The auxiliary base member 101 is made of, for example, a synthetic resin and has an insulating property. A plurality of wirings 102 are provided on the surface of the auxiliary base member 101. The wiring 102 is, for example, a conductive layer (metal layer) provided on the surface of the auxiliary base member 101. The auxiliary base member 101 is disposed between the base member 41T and the flat surface portion 111 of the metal plate 110 in the Z direction. The auxiliary base member 101 faces the electronic component 10TB from the −Z direction side. The terminal 13 of the electronic component 10TB is electrically connected to the wiring 102 provided on the auxiliary base member 101 at a position between the base member 41T and the flat surface portion 111 of the metal plate 110. The auxiliary base member 101 is an example of a “third base member”.

### <6.4 Metal Portion>

### <6.4.1 Structure of Metal Portion>

Next, the metal portion 90 will be described with reference to FIG. 14. The metal portion 90 is, for example, a structure that reduces thermal interference from an external device to the electronic component 10 included in the subunit SUT.

The metal portion 90 is, for example, a heat transfer portion that transfers part of heat directed from an external device to the electronic component 10 (for example, the electronic component 10T) via the bus bar 76 to the flat surface portion 111 of the metal plate 110 that will be described later. Alternatively, the metal portion 90 may be a heat transfer portion that transfers at least part of heat generated by the electronic component 10 and/at least part of heat generated by the bus bar 42 itself to the flat surface portion 111 of the metal plate 110. The flat surface portion 111 of the metal plate 110 is disposed away from the bus bar 42 in the Z direction. The flat surface portion 111 of the metal plate 110 faces the bus bar 42 in the Z direction. The flat surface portion 111 of the metal plate 110 is an example of a “facing portion”.

The metal portion 90 is, for example, a heat storage member (heat absorbing member) that increases the heat capacity of the energization path included in the subunit SUT. The metal portion 90 stores (absorbs) part of heat transferred from an external device to the electronic component 10 (for example, the electronic component 10T) via the bus bar 76, for example. Alternatively, the metal portion 90 may store (absorb) at least part of heat generated by the electronic component 10 and/at least part of heat generated by the bus bar 42 itself. In a case where the metal portion 90 is used as a heat storage member, the metal portion 90 need not be thermally connected to the metal plate 110.

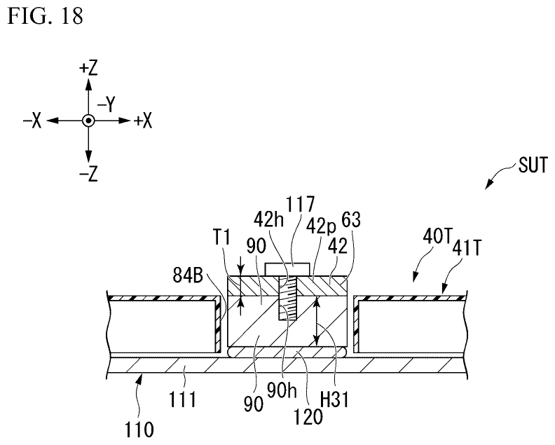

FIG. 17 is a cross-sectional view taken along line F17-F17 of the structure illustrated in FIG. 15. FIG. 18 is a cross-sectional view taken along line F18-F18 of the structure illustrated in FIG. 15. In the present embodiment, the metal portion 90 is provided separately from the metal plate 110. The metal portion 90 is, for example, a solid metal block. The shape of the metal portion 90 is not limited to the above example. The metal portion 90 may be a member having an I-shaped, L-shaped, or C-shaped cross-sectional shape. The metal portion 90 may be integrally formed with the base member 41T through insert molding.

A thickness H31 of the metal portion 90 in the Z direction is larger than the thickness T1 of the horizontal plate portion 42p of the bus bar 42 in the Z direction. For example, the thickness H31 of the metal portion 90 in the Z direction is twice or more the thickness T1 of the horizontal plate portion 42p of the bus bar 42 in the Z direction.

In the present embodiment, a width W31 of the metal portion 90 in the X direction is larger than a width W32 of the electronic component 10 in the X direction (see FIG. 15). From another point of view, the width W31 (see FIG. 15) of the metal portion 90 in the X direction is larger than the above thickness H31 (see FIG. 18) of the metal portion 90 in the Z direction.

In the present embodiment, the base member 41T is disposed between the bus bar 42 and the flat surface portion 111 of the metal plate 110. The base member 41T has an accommodation portion 84B that is open in the Z direction. At least a part of the metal portion 90 is accommodated in the accommodation portion 84B.

The metal portion 90 is disposed between the bus bar 42 and the flat surface portion 111 of the metal plate 110 in the Z direction. The metal portion 90 faces the bus bar 42 from the Z direction and is thermally connected to the bus bar 42.

In the present embodiment, the metal portion 90 is disposed, for example, between the extending portion 63 of the bus bar 42 and the flat surface portion 111 of the metal plate 110. The metal portion 90 faces the extending portion 63 of the bus bar 42 from the Z direction, and is thermally connected to the extending portion 63 of the bus bar 42.

In the present embodiment, the metal portion 90 has an engagement hole 90h that is open in the +Z direction. The inner peripheral surface of the engagement hole 90h has a screw groove. The extending portion 63 of the bus bar 42 has a through-hole 42h facing the engagement hole 90h. A fastening member 117 (for example, a screw or a bolt) passes through the through-hole 42h of the bus bar 42 from the +Z direction side. When the fastening member 117 that has passed through the through-hole 42h of the bus bar 42 is engaged with the engagement hole 90h of the metal portion 90, the extending portion 63 of the bus bar 42 is fixed to the metal portion 90.

In the present embodiment, the heat transfer member 120 is disposed between the metal portion 90 and the flat surface portion 111 of the metal plate 110. Instead of/in addition to the above example, the heat transfer member 120 may be disposed between the metal portion 90 and the bus bar 42.

As illustrated in FIG. 15, when viewed from the Z direction, the metal portion 90 is disposed between the terminal 13B of the electronic component 10 and the external connection bus bar 76. Therefore, heat directed from the bus bar 76 to the electronic component 10 through the bus bar 42 easily moves to the metal portion 90 before reaching the electronic component 10.

The metal portion 90 includes, for example, a first portion 91 and a second portion 92. The first portion 91 is located on the +Y direction side with respect to the terminal 13B of the electronic component 10 when viewed from the Z direction. The second portion 92 is located on the −X direction side or the +X direction side with respect to the terminal 13B of the electronic component 10 when viewed from the Z direction. The first portion 91 and the second portion 92 are integrally formed. According to such a constitution, it is easy to secure a larger volume of the metal portion 90 compared with the metal portion 90 having a rectangular parallelepiped shape.

### <6.4.2 Modification Examples of Metal Portion>

Next, modification examples of the metal portion 90 will be described. Note that a constitution other than that described below in each modification example is the same as the constitution of the first embodiment.

### (First Modification Example)

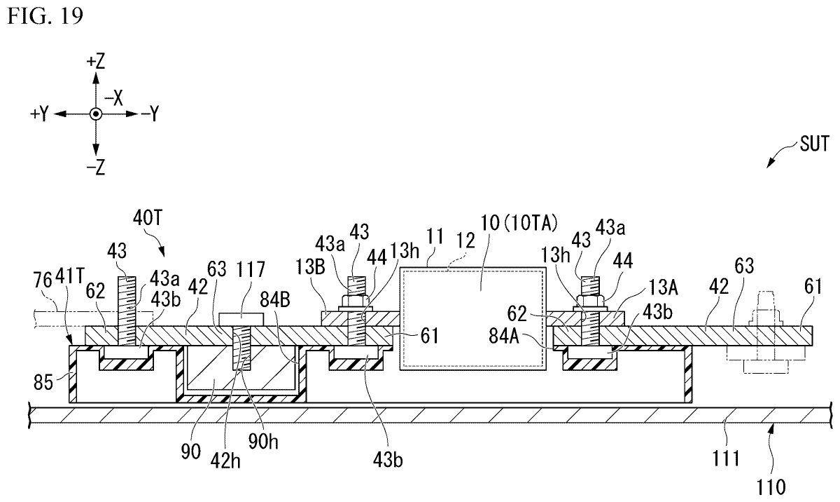

FIG. 19 is a cross-sectional view illustrating a subunit SUT of a first modification example. In the above-described embodiment, the metal portion 90 is thermally connected to the metal plate 110 and functions as a heat transfer portion. On the other hand, in the present modification example, the metal portion 90 is not thermally connected to the metal plate 110. The metal portion 90 functions as a heat storage member (heat absorbing member). For example, a part of the base member 41T is provided between the metal portion 90 and the metal plate 110.

### (Second Modification Example)

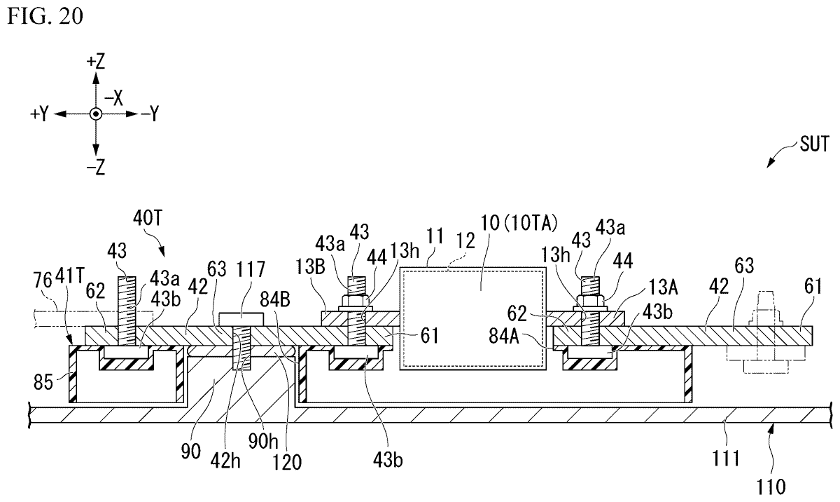

FIG. 20 is a cross-sectional view illustrating a subunit SUT of a second modification example. In the above-described embodiment, the metal portion 90 and the metal plate 110 are formed as separate bodies. On the other hand, in the present modification example, the metal portion 90 and the metal plate 110 are formed as one piece member. The metal portion 90 is provided as a part of the metal plate 110 and is formed integrally with the flat surface portion 111. The metal portion 90 is a protruding portion protruding from the flat surface portion 111 toward the bus bar 42. In the example illustrated in FIG. 20, the heat transfer member 120 is disposed between the metal portion 90 and the bus bar 42.

### (Third Modification Example)

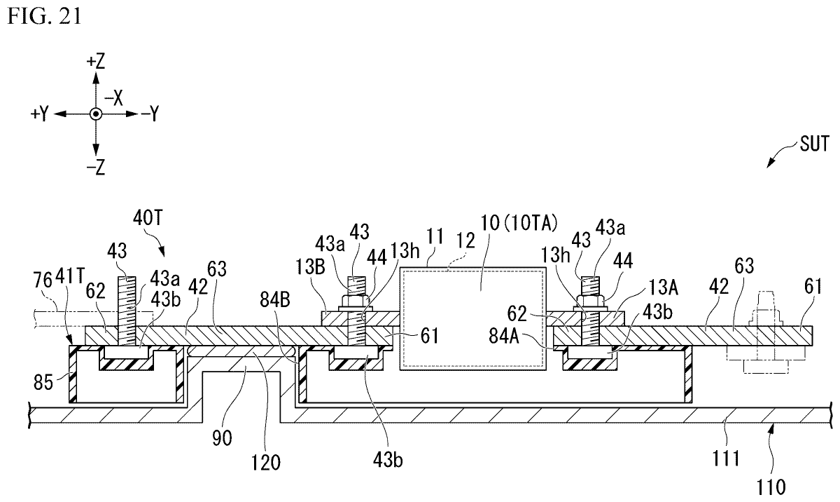

FIG. 21 is a cross-sectional view illustrating a subunit SUT of a third modification example. In the present modification example, the metal portion 90 is provided by deforming a part of the flat surface portion 111 of the metal plate 110 toward the +Z direction side through press working or the like. Also in the present modification example, the metal portion 90 is provided as a part of the metal plate 110 and is formed integrally with the flat surface portion 111. The metal portion 90 is a protruding portion protruding from the flat surface portion 111 toward the bus bar 42. In the example illustrated in FIG. 21, the heat transfer member 120 is disposed between the metal portion 90 and the bus bar 42.

### (Fourth Modification Example)

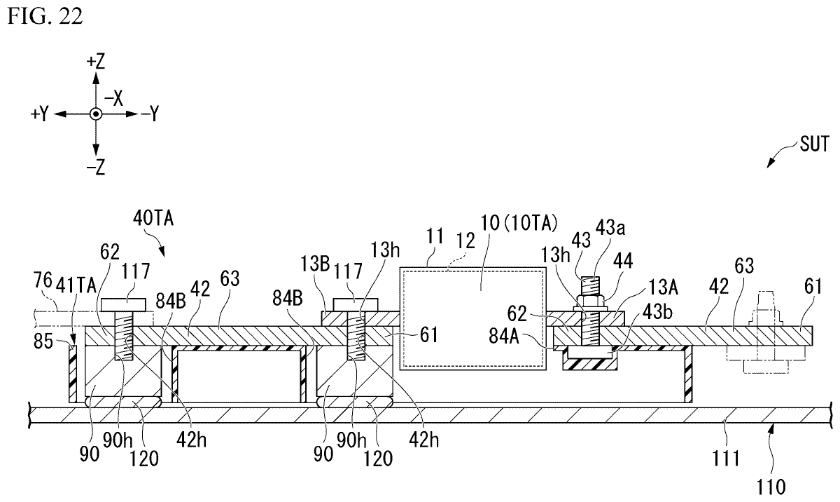

FIG. 22 is a cross-sectional view illustrating a subunit SUT of a fourth modification example. In the above-described embodiment, the metal portion 90 is fixed to the extending portion 63 of the bus bar 42. Alternatively, the metal portion 90 may be fixed to at least one of the connection portion 61 and the connection portion 62 of the bus bar 42. For example, the terminal 13 of the electronic component 10 and the connection portion 61 of the bus bar 42 may be fastened together by the fastening member 117 that fixes the bus bar 42 to the metal portion 90, or the external connection bus bar 76 and the connection portion 62 of the bus bar 42 may be fastened together. In addition, the metal portion 90 provided to correspond to the connection portion 61 or the connection portion 62 of the bus bar 42 may have any one of the aspects of the first to third modification examples described above.

### <7. Coupling Structure of Subunit>

Next, a coupling structure between the plurality of subunits SU will be described.

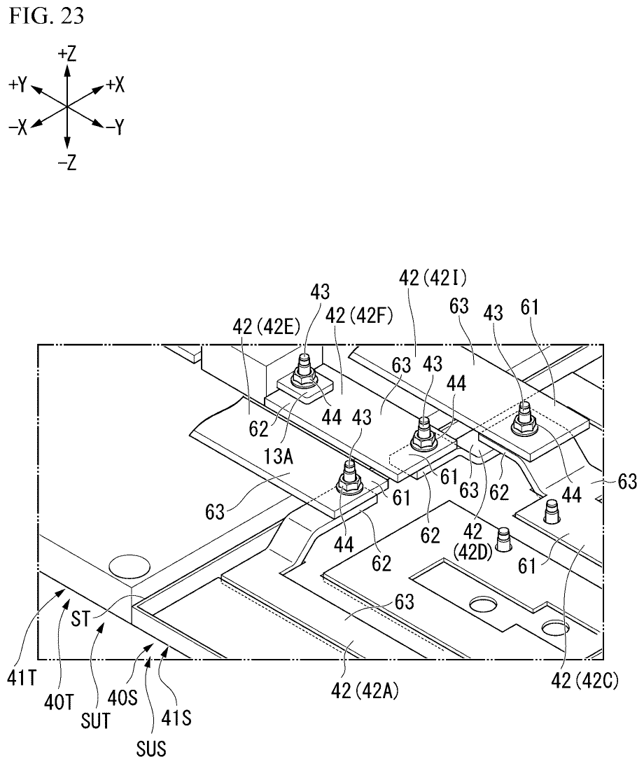

FIG. 23 is a perspective view illustrating a coupling structure between the subunit SUS and the subunit SUT. In the present embodiment, a step ST based on a difference in height in the Z direction between the base plate 41S of the subunit SUS and the base member 41T of the subunit SUT is formed between the subunit SUS and the subunit SUT. An intersection structure in which the bus bar 42 included in the subunit SUS and the bus bar 42 included in the subunit SUT three-dimensionally intersect is realized by using the step ST.

For example, the bus bars 42E, 42F, and 42I included in the subunit SUT maintain the height in the Z direction supported by the base member 41T and extend in the −Y direction to a position overlapping the base plate 41S of the subunit SUS in the Z direction. The connection portion 61 of each of the bus bars 42E, 42F, and 42I is separated from the base plate 41S of the subunit SUS in the Z direction and faces the base plate 41S of the subunit SUS in the Z direction.

On the other hand, the connection portion 62 of the bus bar 42A included in the subunit SUS is raised in the +Z direction with respect to the extending portion 63 of the bus bar 42A, and is in contact with the connection portion 61 of the bus bar 42E from the −Z direction side. The connection portion 62 of the bus bar 42A and the connection portion 61 of the bus bar 42E are fixed by the fastening member 43 and the engagement member 44.

Similarly, the connection portion 62 of the bus bar 42C included in the subunit SUS is raised in the +Z direction with respect to the extending portion 63 of the bus bar 42C, and is in contact with the connection portion 61 of the bus bar 42I from the −Z direction side. The connection portion 62 of the bus bar 42C and the connection portion 61 of the bus bar 42I are fixed by the fastening member 43 and the engagement member 44.

The extending portion 63 of the bus bar 42D included in the subunit SUS extends in the X direction through between the flat surface portion 111 of the metal plate 110 and the bus bar 42I. For example, the extending portion 63 of the bus bar 42D passes through a region overlapping the bus bar 42I when viewed from the Z direction, and extends over the +X direction side and the −X direction side of the bus bar 42I. The connection portion 62 of the bus bar 42D is raised in the +Z direction with respect to the extending portion 63 of the bus bar 42D, and is in contact with the connection portion 61 of the bus bar 42F from the −Z direction side. The connection portion 62 of the bus bar 42D and the connection portion 61 of the bus bar 42F are fixed by the fastening member 43 and the engagement member 44.

### <8. Extending Structure of Bus Bar>

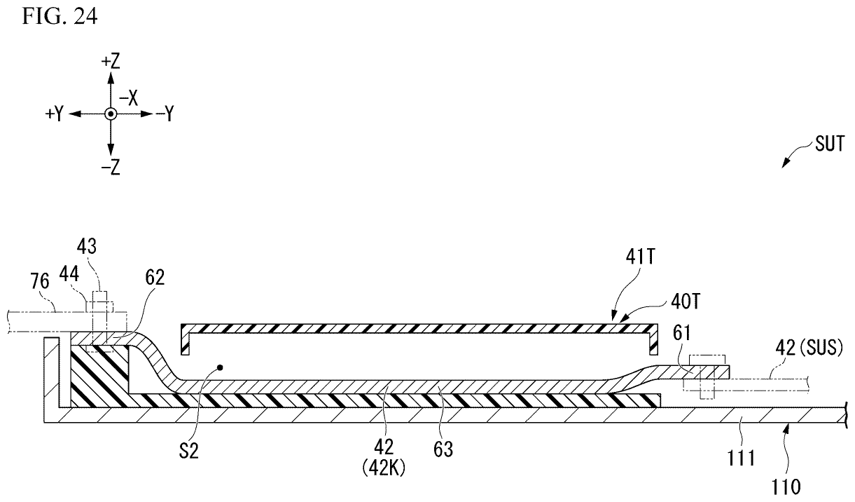

FIG. 24 is a cross-sectional view taken along line F24-F24 of the structure illustrated in FIG. 15. In the present embodiment, one bus bar 42 (bus bar 42K) is disposed between the base member 41T and the flat surface portion 111 of the metal plate 110, and extends in the Y direction in a gap S2 between the base member 41T and the flat surface portion 111 of the metal plate 110. The bus bar 42K extends, for example, over the −Y direction side and the +Y direction side of the base member 41T. The connection portion 61 of the bus bar 42K is physically and electrically connected to the bus bar 42 included in the subunit SUS. The connection portion 62 of the bus bar 42K is physically and electrically connected to the external connection bus bar 76. The bus bar 42K is an example of a “third bus bar”.

### <9. Metal Plate and Insulating Cover>

Next, referring to FIG. 2 again, the metal plate 110 and the insulating cover 130 will be described.

### <9.1 Metal Plate>

The metal plate 110 is a member that secures rigidity of the electrical connection unit 1 and enhances the heat dissipation property of the electrical connection unit 1. The metal plate 110 is made of metal (for example, aluminum or an aluminum alloy). The metal plate 110 is an example of a “rigid member”. The metal plate 110 may be referred to as a “metal member” or a “heat dissipation member”.

The metal plate 110 has a rectangular shape formed in the X direction and the Y direction. The metal plate 110 has a first end 110e1, a second end 110e2, a third end 110e3, and a fourth end 110e4. The first end 110e1 and the second end 110e2 are a pair of ends of the metal plate 110 in the longitudinal direction, and are separated in the X direction. The third end 110e3 and the fourth end 110e4 are a pair of ends of the metal plate 110 in the lateral direction, and are separated in the Y direction. The metal plate 110 includes, for example, the flat surface portion 111, the plurality of fixing portions 112 (see FIG. 9) described above, and the plurality of fixing portions 113 (see FIG. 9) described above.

The flat surface portion 111 is a portion formed in a plate shape in the metal plate 110. The flat surface portion 111 has a plate shape formed in the horizontal direction. The flat surface portion 111 forms a main portion of the metal plate 110. The flat surface portion 111 forms a base portion (metal base portion) of the metal plate 110. The flat surface portion 111 has a size that covers the two subunits SU from below.

In the present embodiment, the flat surface portion 111 has a first region A1 and a second region A2. The first region A1 is, for example, a region on the −Y direction side in the flat surface portion 111. The subunit SUS described above faces the first region A1 of the flat surface portion 111 when viewed from the Z direction. That is, the plurality of electronic components 10S and the base plate 41S included in the subunit SUS face the first region A1 of the flat surface portion 111 in the Z direction.

The second region A2 is, for example, a region on the +Y direction side in the flat surface portion 111. The above-described subunit SUT faces the second region A2 of the flat surface portion 111 when viewed from the Z direction. That is, the plurality of electronic components 10T and the base member 41T included in the subunit SUT face the second region A2 of the flat surface portion 111 in the Z direction.

### <9.2 Insulating Cover>

The insulating cover 130 is a member for preventing the subunit SU from contacting the energization path. The insulating cover 130 is made of, for example, a synthetic resin and has an insulating property. The insulating cover 130 has, for example, a box shape that is open on the −Z direction side. The insulating cover 130 has a plurality of vent holes 130h. The insulating cover 130 covers a part or the whole of the corresponding subunit SU. Note that the insulating cover 130 is not limited to a box-shaped member, and may be a sheet-shaped member that covers the energization path of the main body MU. The insulating cover 130 may be omitted.

### <10. Advantages>

### <A. Advantages Related to Plurality of Region Division in Electrical Connection Unit>

As a comparative example, a constitution in which an electronic component of which a heat dissipation property is to be prioritized and an electronic component of which a mountability is to be prioritized are attached to one base member will be considered. In such a constitution, it may be difficult to improve the mountability when a thin base member is adopted, and it may be difficult to improve the heat dissipation property when a relatively thick base member is adopted.

On the other hand, the electrical connection unit (for example, the electrical connection unit 1) of the present embodiment includes a rigid member (for example, the metal plate 110), a first electronic component (for example, the electronic component 10S), a first base member (for example, the base plate 41S), a first bus bar (for example, the bus bars 42A, 42B, 42C, and 42D), a second electronic component (for example, the electronic component 10T), a second base member (for example, the base member 41T), and a second bus bar (for example, the bus bars 42E, 42F, 42G, and 42I). The rigid member includes a first region (for example, first region A1) and a second region (for example, second region A2). The first electronic component faces the first region in the first direction. The first base member faces the first region in the first direction, has a flat surface portion (for example, the flat surface portion 51), and has an insulating property. The first bus bar is supported by the flat surface portion and electrically connected to the first electronic component. The second electronic component faces the second region in the first direction, and has a smaller amount of heat generation than the first electronic component. The second base member faces the second region in the first direction, has a three-dimensional structure thicker in the first direction than the first base member, and has an insulating property. The second bus bar is supported by the second base member and electrically connected to the second electronic component.

According to such a constitution, by using the first base member having the flat surface portion, it is possible to dispose the first electronic component in which the heat dissipation property is emphasized, near the rigid member and to promote heat release with the rigid member as a heat dissipation member. On the other hand, by using the second base member having a thick three-dimensional structure in the first direction, it is possible to appropriately mount the second electronic component in which the mountability is emphasized. By using such regions properly, it is possible to provide an electrical connection unit that achieves both a heat dissipation property and a mountability.

In the present embodiment, the first electronic component faces the flat surface portion. The second base member has an accommodation portion (for example, the accommodation portion 84A) recessed in the first direction or penetrating the second base member in the first direction. At least a part of the second electronic component is accommodated in the accommodation portion. According to such a constitution, it is possible to dispose the second electronic component in the accommodation portion of the second base member while enhancing the heat dissipation property by exposing the first electronic component in which the heat dissipation property is emphasized to the outside of the first base member. With this constitution, even when a relatively thick second base member is used, the height of the entire electrical connection unit can be reduced.

In the present embodiment, the electrical connection unit further includes a heat transfer member (for example, the heat transfer member 120). The first bus bar includes an exposed portion (for example, the exposed portion 42u) exposed to a gap between the flat surface portion and the rigid member. The heat transfer member is disposed between the exposed portion of the first bus bar and the rigid member. According to such a constitution, it is possible to more firmly thermally connect the first electronic component in which the heat dissipation property is emphasized and the rigid member. Such thermal connection can further improve the heat dissipation property.

In the present embodiment, the first electronic component has a terminal (for example, a terminal 13) directed in a second direction different from the first direction. The second electronic component includes a terminal (for example, the terminal 13) protruding in the first direction toward the rigid member. Here, the second electronic component having a terminal protruding in the first direction toward the rigid member is an electronic component of which a mounting structure tends to be complicated. However, by using the second base member that is thick in the first direction, it is easy to appropriately mount even the second electronic component of which the mounting structure tends to be complicated. This mounting structure can improve the mountability.

In the present embodiment, the electrical connection unit further includes a third base member (for example, the auxiliary base member 101). The third base member is disposed between the second base member and the rigid member in the first direction, and is provided with a wiring (for example, the wiring 102) to which a terminal of the second electronic component is electrically connected. According to such a constitution, by disposing the third base member between the second base member and the rigid member, even the second electronic component of which the mounting structure tends to be complicated can be easily mounted appropriately. This mounting structure can improve the mountability.

In the present embodiment, the second bus bar protrudes from the second base member to a position overlapping the first base member in the first direction. The first bus bar extends between the rigid member and the second bus bar. According to such a constitution, it is possible to realize an intersection structure in which the first bus bar and the second bus bar three-dimensionally intersect each other by utilizing a difference in thickness between the first base member and the second base member. This intersection structure can increase the degree of freedom of routing in the electrical connection unit and/or the degree of freedom of component disposition.

In the present embodiment, the electrical connection unit further includes a third bus bar (for example, the bus bar 42K). The third bus bar is disposed between the second base member and the rigid member in the first direction, and is electrically connected to the first bus bar. According to such a constitution, the third bus bar can be disposed by using the gap between the second base member and the rigid member. The disposition of the bus bar can increase the degree of freedom of routing in the electrical connection unit and/or the degree of freedom of component disposition.

### <B. Advantages Related to Metal Portion>

As a comparative example, a constitution in which the metal portion 90 is not provided will be considered. In such a constitution, for example, in a case where the bus bar 42 does not have a sufficiently large heat capacity, when heat is transferred from the bus bar 76 to the bus bar 42, thermal interference with the electronic component 10 may increase. Therefore, it may be difficult to improve thermal characteristics.

On the other hand, the electrical connection unit (for example, the electrical connection unit 1) of the present embodiment includes a first electronic component (for example, the electronic component 10), a bus bar (for example, the bus bar 42), and a metal portion (for example, the metal portion 90). The bus bar includes a plate portion (for example, the horizontal plate portion 42p), and is electrically connected to the first electronic component. The metal portion faces the bus bar in a first direction that is a thickness direction of the plate portion, and is thermally connected to the bus bar. A thickness (for example, the thickness H31) of the metal portion in the first direction is twice or more a thickness (for example, the thickness T1) of the plate portion. According to such a constitution, at least part of the heat transferred to the bus bar is stored (absorbed) by the metal portion. This heat storage operation can improve the thermal characteristics of the electrical connection unit.

In the present embodiment, the bus bar includes a first connection portion (for example, the connection portion 61), a second connection portion (for example, the connection portion 62), and an extending portion (for example, the extending portion 63). The first connection portion is electrically connected to the first electronic component (for example, the electronic component 10). The second connection portion is electrically connected to a second electronic component (for example, the electronic component 10) or an external connection component (for example, the bus bar 76). The extending portion extends between the first connection portion and the second connection portion. At least a part of the metal portion faces the extending portion of the bus bar. According to such a constitution, the metal portion can be provided without interfering with the fastening structure provided in the first connection portion or the second connection portion. With this structure, the degree of freedom of the shape or size of the metal portion is increased, and the thermal characteristics of the electrical connection unit can be further improved.

In the present embodiment, in a case where an extending direction of the bus bar is a second direction, and a direction intersecting the first direction and the second direction is a third direction, a width of the metal portion in the third direction is larger than a width of the first electronic component in the third direction. According to such a constitution, the metal portion larger than the width of the bus bar is disposed, and the heat capacity can be greatly increased by the metal portion. This increase in heat capacity can further improve the thermal characteristics of the electrical connection unit.

In the present embodiment, the electrical connection unit further includes a rigid member (for example, a metal plate 110) in addition to the first electronic component, the bus bar, and the metal portion. The rigid member includes a facing portion (for example, the flat surface portion 111) facing the bus bar in the first direction. The metal portion is provided as a part or a separate body of the metal member. The metal portion is disposed between the bus bar and the facing portion in the first direction. According to such a constitution, the metal portion can cause at least part of the heat of the bus bar to move to the rigid member, and the rigid member can be utilized as a heat dissipation member to release the heat. This heat dissipation operation can further improve the thermal characteristics of the electrical connection unit.

In the present embodiment, the electrical connection unit further includes a heat transfer member. The heat transfer member is disposed between the bus bar and the metal portion or between the metal portion and the facing portion. According to such a constitution, the thermal connection between the bus bar and the rigid member can be further strengthened. This thermal connection can further improve the thermal characteristics of the electrical connection unit.

In the present embodiment, the electrical connection unit further includes a base member (for example, the base member 41T). The base member is disposed between the bus bar and the facing portion in the first direction. The base member supports the bus bar and has an insulating property. The base member has an accommodation portion (for example, the accommodation portion 84B) that is open in the first direction. At least a part of the metal portion is disposed in the accommodation portion. According to such a constitution, even if the metal portion is provided, it is possible to avoid an increase in size of the electrical connection unit. With this structure, it is possible to facilitate miniaturization (for example, reduction in height) of the electrical connection unit.

In the present embodiment, the metal portion is a metal block provided separately from the rigid member. According to such a constitution, it is easy to increase the heat capacity more by using the metal portion. This increase in heat capacity can further improve the thermal characteristics of the electrical connection unit.

In the present embodiment, the metal portion is a protruding portion provided as a part of the rigid member and protruding in the first direction from the facing portion. According to such a constitution, the metal portion can be provided by using a part of the rigid member. With this structure, it is possible to reduce the cost of the electrical connection unit.

### <C. Advantages Related to First Shape Example of Bus Bar>

As a comparative example, a bus bar in which the width of the connection portion 61 and the width of the extending portion 63 are the same will be considered. In such a constitution, the temperature locally may rise at the connection portion 61 connected to the electronic component 10 compared with the extending portion 63, and it may be difficult to improve the thermal characteristics of the electrical connection unit.

On the other hand, the bus bar (for example, the bus bar 42) of the present embodiment has a first connection portion (for example, the connection portion 61) and a first extending portion (for example, the first straight portion 63a of the extending portion 63). The first connection portion is connected to a first terminal (for example, terminal 13A) of an electronic component (for example, electronic component 10) directly or via a first connection component (for example, connection component 20A). The first extending portion extends from the first connection portion. In a case where a thickness direction of the first extending portion is a first direction, an extending direction of the first extending portion is a second direction, and a direction intersecting the first direction and the second direction is a third direction, a width (for example, the width W11) of the first connection portion in the third direction is larger than a width (for example, the W12) of the first extending portion in the third direction.

According to such a constitution, the width of the first connection portion connected to the electronic component is enlarged, and thermal characteristics (for example, the heat storage property and/or the heat dissipation property) of the first connection portion are enhanced. With this structure, it is possible to suppress a local temperature rise in the first connection portion compared with the first extending portion, and it is possible to improve the thermal characteristics of the electrical connection unit.

In the present embodiment, the first connection portion has a first edge (for example, the edge 61e1) extending in the second direction and a second edge (for example, the edge 61e2) located on a side opposite to the first edge in the third direction and extending in the second direction. The first extending portion has a third edge (for example, the edge 63e1) extending in the second direction and a fourth edge (for example, the edge 61e2) located on a side opposite to the third edge in the third direction and extending in the second direction. The first edge and the third edge are linearly continuous in the first direction. A step in the third direction exists between the second edge and the fourth edge. According to such a constitution, the width of the first connection portion is enlarged compared with the first extending portion, and another component (for example, the electronic component 10 or the bus bar 42) is easily disposed along the first edge and the third edge which are linearly continuous. With this structure, the electrical connection unit can be miniaturized.

In the present embodiment, the electrical connection unit further includes a base member (for example, the base plate 41S) in addition to the bus bar. The base member includes a flat surface portion (for example, the flat surface portion 51) and has an insulating property. The base member has an accommodation portion (for example, the accommodation portion 55) recessed in the first direction or penetrating the base member in the first direction. At least a part of the first connection portion and at least a part of the first extending portion are accommodated in the accommodation portion. In the accommodation portion, a width of the first connection portion in the third direction is larger than a width of the first extending portion in the third direction. According to such a constitution, since at least a part of the first connection portion and at least a part of the first extending portion are accommodated in the accommodation portion of the base member, even if the width of the first connection portion is enlarged compared with the first extending portion, a dead space is less likely to occur in the electrical connection unit. With this structure, it is possible to provide an electrical connection unit that is further advantageous for miniaturization.

In the present embodiment, the electrical connection unit further includes a first connection component (for example, the connection component 20A). A width of the first extending portion in the third direction is equal to or smaller than a width (for example, the width W13) of the first connection component in the third direction. On the other hand, a width of the first connection portion in the third direction is larger than a width of the first connection component in the third direction. According to such a constitution, the first connection portion is enlarged beyond the originally necessary width. With this structure, the thermal characteristics of the electrical connection unit can be further improved.

The electrical connection unit further includes a second bus bar (for example, the bus bar 42B). The second bus bar includes a second connection portion (for example, the connection portion 61) and a second extending portion (for example, the first straight portion 63a of the extending portion 63). The second connection portion is adjacent to the first connection portion in the third direction and is connected to a second terminal (for example, the terminal 13B) of the electronic component directly or via a second connection component (for example, the connection component 20B). The second extending portion is adjacent to the first extending portion in the third direction and extends from the second connection portion in the second direction. The first connection portion protrudes to a side opposite to the second bus bar with respect to the first extending portion. The second connection portion protrudes to a side opposite to the first bus bar with respect to the second extending portion. According to such a constitution, even in a case where each of the first connection portion of the first bus bar and the second connection portion of the second bus bar is enlarged in the third direction, the first bus bar and the second bus bar can be disposed close to each other. With this structure, the electronic connection unit can be further miniaturized.

### <D. Advantages Related to Second Shape Example of Bus Bar>

As a comparative example, a bus bar in which the extending portion 63 extends from the connection portion 61 toward the connection portion 62 at the shortest distance will be considered. In such a constitution, heat may be easily transferred from the connection portion 61 to the connection portion 62, and it may be difficult to improve thermal characteristics of the electrical connection unit.

On the other hand, the bus bar (for example, the bus bar 42) of the present embodiment includes a first connection portion (for example, the connection portion 61), a second connection portion (for example, the connection portion 62), a first extending portion (for example, the first straight portion 63a of the extending portion 63), and a second extending portion (for example, the second straight portion 63b of the extending portion 63). The first connection portion is connected to the first electronic component (for example, the electronic component 10A) directly or via a connection component (for example, the connection component 20B). The second connection portion is connected to the second electronic component (for example, the electronic component 10B) directly or via a connection component (for example, the connection component 20C). The first extending portion extends from the first connection portion in a direction different from a direction from the first connection portion toward the second connection portion. The first extending portion includes a first portion and a second portion. The first portion is coupled to the first extending portion. The second portion is located on a side opposite to the first portion with respect to the second connection portion in the extending direction of the first extending portion. The second extending portion extends from the second portion of the first extending portion in a direction approaching the second connection portion.

According to such a constitution, the first extending portion does not extend from the first connection portion toward the second connection portion at the shortest distance, but extends while intentionally detouring. When the bus bar has the extending portion extending while detouring, the portion extending while detouring in the bus bar can have enhanced thermal characteristics (for example, the heat storage property and/or the heat dissipation property). This structure can improve the thermal characteristics of the electrical connection unit.

In the present embodiment, the bus bar further includes a third extending portion (for example, the third straight portion 63c). The second extending portion extends in a direction approaching the second connection portion from the second portion of the first extending portion, the direction being different from a direction from the second portion of the first extending portion toward the second connection portion at the shortest distance. According to such a constitution, the second extending portion does not extend from the first extending portion toward the second connection portion at the shortest distance, but intentionally extends while detouring. With this structure, the thermal characteristics (for example, the heat storage property and/or the heat dissipation property) of the bus bar can be further improved, and the thermal characteristics of the electrical connection unit can be further improved.

In the present embodiment, the first extending portion and the second extending portion are located on the same plane. In a case where a thickness direction of the first extending portion and the second extending portion is a first direction, an extending direction of the first extending portion is a second direction, and an extending direction of the second extending portion is a third direction, a width (for example, the width W23) of the second extending portion in a direction intersecting the first direction and the third direction is larger than a width (for example, the width W22) of the first extending portion in a direction intersecting the first direction and the second direction. According to such a constitution, the width of the second extending portion is enlarged, and thermal characteristics (for example, the heat storage property and/or the heat dissipation property) of the second extending portion are enhanced. With this structure, it is possible to suppress a local temperature rise at the first connection portion or the second connection portion, and it is possible to improve the thermal characteristics of the electrical connection unit.

In the present embodiment, the electrical connection unit further includes an insulating base member (for example, the base plate 41S) including a flat surface portion (for example, the flat surface portion 51). The base member includes an accommodation portion (for example, the accommodation portion 55) recessed in a first direction that is a thickness direction of the plate portion or penetrating the base member in the first direction. At least a part of the first extending portion and at least a part of the second extending portion are accommodated in the accommodation portion. In the accommodation portion, the width of the second extending portion is larger than the width of the first extending portion. According to such a constitution, since at least a part of the first extending portion and at least a part of the second extending portion are accommodated in the accommodation portion of the base member, even if the width of the second extending portion is enlarged compared with the first extending portion, a dead space is less likely to occur in the electrical connection unit. With this structure, it is possible to provide an electrical connection unit that is further advantageous for miniaturization.

In the present embodiment, when the thickness direction of the plate portion is the first direction, at least a part of the first extending portion overlaps the first electronic component in the first direction, and the second extending portion does not overlap the first electronic component and the second electronic component in the first direction. According to such a constitution, the width of the second extending portion is enlarged in a region not overlapping the electronic component (a region where the electronic component hardly hinders heat dissipation). With this structure, heat can be favorably released from the second extending portion having an enlarged width, and the thermal characteristics of the electrical connection unit can be further improved.

### <11. Modification Examples>

Next, several modification examples will be described. Note that a constitution other than that described below in each modification example is the same as the constitution of the above-described embodiment.

### (First Modification Example)

The routing board 40S is not limited to a structure in which the base plate 41S and the bus bar 42 are integrated through insert molding. For example, the bus bar 42 may be disposed in the accommodation portion 55 after the base plate 41S provided with the accommodation portion 55 accommodating the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

### (Second Modification Example)

The base member of the routing board 40S is not limited to the base plate 41S having the plate-shaped flat surface portion 51. The routing board 40S may be a base member (for example, an insulating sheet) having a sheet-shaped flat surface portion 51. In this case, the accommodation portion 55 may be formed by a part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### (Third Modification Example)

The base plate 41S of the routing board 40S may include a plurality of members (plate members or sheet members). The plurality of members are provided to sandwich the plurality of bus bars 42 arranged in the horizontal direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41S (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed.

### (Fourth Modification Example)

A connection between the electronic component 10 and the bus bar 42 is not limited to the connection using the connection component 20. The electronic component 10 may be directly connected to the bus bar 42 by using a fastening member (for example, a bolt or a screw), welding, or the like.

Several embodiments and modification examples have been described above. However, the embodiment and the modification examples are not limited to the examples described above. For example, the plurality of modification examples described above may be implemented in combination with each other.

### DESCRIPTION OF REFERENCE SYMBOLS

1 Electrical connection unit
SU, SUS, SUT Subunit
10, 10S, 10T, 10TA, 10TB Electronic component
13, 13A, 13B Terminal
20 Connection component
40S Routing board
40T Routing structure
41S Base plate
41T Base member
42 Bus bar
51 Flat surface portion
52 Frame portion
55 Accommodation portion
61 Connection portion
62 Connection portion
63 Extending portion
63a First straight portion
63aa First end (first portion)
63ab Second end (second portion)
63b Second straight portion
63c Third straight portion
84A, 84B Accommodation portion
85 Frame portion
90 Metal portion
101 Auxiliary base member
102 Wiring
110 Metal plate (rigid member, metal member, heat dissipation member)
111 Flat surface portion (facing portion)
120 Heat transfer member

1. A bus bar comprising:
a first connection portion that is connected to a first terminal of an electronic component directly or via a first connection component; and
a first extending portion extending from the first connection portion,
wherein in a case where a thickness direction of the first extending portion is a first direction, an extending direction of the first extending portion is a second direction, and a direction intersecting the first direction and the second direction is a third direction, a width of the first connection portion in the third direction is larger than a width of the first extending portion in the third direction.

2. The bus bar according to claim 1,
wherein the first connection portion has a first edge extending in the second direction and a second edge located on a side opposite to the first edge in the third direction and extending in the second direction,
wherein the first extending portion has a third edge extending in the second direction and a fourth edge located on a side opposite to the third edge in the third direction and extending in the second direction,
wherein the first edge and the third edge are linearly continuous in the second direction, and
wherein a step in the third direction is present between the second edge and the fourth edge.

3. An electrical connection unit comprising:
the electronic component; and
the bus bar according to claim 1.

4. The electrical connection unit according to claim 3, further comprising:
an insulating base member including a flat surface portion,
wherein the base member includes an accommodation portion recessed in the first direction or penetrating the base member in the first direction,
wherein at least a part of the first connection portion and at least a part of the first extending portion are accommodated in the accommodation portion, and
wherein a width of the first connection portion in the third direction is larger than a width of the first extending portion in the third direction inside the accommodation portion.

5. The electrical connection unit according to claim 3, further comprising:
the first connection component,
wherein the width of the first extending portion in the third direction is equal to or smaller than a width of the first connection component in the third direction, and
wherein the width of the first connection portion in the third direction is larger than the width of the first connection component in the third direction.

6. The electrical connection unit according to claim 3, further comprising:
a second bus bar in a case where the bus bar is a first bus bar,
wherein the second bus bar includes: a second connection portion that is adjacent to the first connection portion in the third direction and is connected to a second terminal of the electronic component directly or via a second connection component; and a second extending portion that is adjacent to the first extending portion in the third direction and extends from the second connection portion in the second direction,
wherein the first connection portion protrudes to a side opposite to the second bus bar with respect to the first extending portion, and
wherein the second connection portion protrudes to a side opposite to the first bus bar with respect to the second extending portion.
